(19) United States
(12) Patent Application Publication
(10) Pub. No.: US 2026/0305237 A1
(43) Pub. Date: Oct. 1, 2026

(54) SUBSTRATE PROCESSING SYSTEM, STORAGE MODULE, AND SUBSTRATE PROCESSING METHOD

(71) Applicant: Tokyo Electron Limited, Tokyo (JP)

(72) Inventor: Nobuyuki NAGAYAMA, Miyagi (JP)

(73) Assignee: Tokyo Electron Limited, Tokyo (JP)

(21) Appl. No.: 19/676,896

(22) Filed: May 14, 2026

Related U.S. Application Data
(63) Continuation of application No. PCT/JP2024/039936, filed on Nov. 11, 2024.

(30) Foreign Application Priority Data
Nov. 24, 2023 (JP) 2023-198857

(51) Int. Cl. H10P 72/10; H10P 72/00; H10P 72/30

(52) U.S. Cl. CPC H10P 72/18; H10P 72/0464; H10P 72/33; H10P 72/3411

(57) ABSTRACT

A substrate processing system includes a processing module to process a substrate, a vacuum transfer module connected to the processing module, an atmospheric transfer module connected to the vacuum transfer module via a load-lock module, and a transferer to transfer, to the processing module, the substrate and a tray on which the substrate is placed, in which the tray is formed with a recess provided in an upper surface of the tray and to accommodate the substrate, and a hole penetrating the tray from the recess to a lower surface of the tray, and the hole movably holds a pin protruding from either the recess or the lower surface in a state where the pin is inserted into the hole.

### CROSS-REFERENCE TO RELATED APPLICATIONS

This application is a bypass continuation application of international application No. PCT/JP2024/039936 having an international filing date of Nov. 11, 2024 and designating the United States, the international application being based upon and claiming the benefit of priority from Japanese Patent Application No. 2023-198857, filed on Nov. 24, 2023, the entire contents of each are incorporated herein by reference.

### TECHNICAL FIELD

The present disclosure relates to a substrate processing system, a storage module, and a substrate processing method.

### BACKGROUND

PTL 1 discloses a substrate processing system for processing a substrate, in which a wafer to be subjected to substrate processing and an edge ring disposed in a manner of surrounding the wafer are electrostatically attracted to a tray having a disk shape, and are transferred to a process module in this state. Further, in the substrate processing system disclosed in PTL 1, the wafer and the edge ring are placed on a susceptor in the process module via the tray, and plasma processing such as etching is performed in this state.

### CITATION LIST

### Patent Documents

PTL 1: JP2021-34390A

### SUMMARY

According to an aspect of the present disclosure, a substrate processing system is provided. The substrate processing system includes: a processing module having a substrate support and configured to process a substrate; a vacuum transfer module connected to the processing module, the vacuum transfer module having an interior maintained at a sub-atmospheric pressure; an atmospheric transfer module connected to the vacuum transfer module via a load-lock module, the atmospheric transfer module having an interior maintained at the atmospheric pressure; and a transferer configured to transfer, to the processing module, the substrate and a tray on which the substrate is placed, in which the tray is formed with a recess provided in an upper surface of the tray to accommodate the substrate, and a hole penetrating the tray from the recess to a lower surface of the tray, and the hole is configured to movably hold a pin configured to protrude from either the recess or the lower surface in a state where the pin is inserted into the hole.

### BRIEF DESCRIPTION OF DRAWINGS

FIG. 1 is a plan view schematically illustrating an example of a configuration of a wafer processing system.

FIG. 2 is a cross-sectional view schematically illustrating an example of a configuration of a wafer processing module.

FIG. 3 is a plan view schematically illustrating an example of a configuration of a tray.

FIG. 4 is a cross-sectional view schematically illustrating an example of a configuration of the tray.

FIG. 5 is a cross-sectional view schematically illustrating a state example of the tray and a wafer.

FIG. 6 is a cross-sectional view schematically illustrating a state example of the tray and the wafer.

FIG. 7 is a cross-sectional view schematically illustrating an example of a configuration of a pin.

FIG. 8 is a plan view schematically illustrating an example of a configuration of the pin.

FIG. 9 is a cross-sectional view schematically illustrating an example of a configuration of a hole.

FIG. 10 is a cross-sectional view schematically illustrating another example of a configuration of the pin.

FIG. 11 is a cross-sectional view schematically illustrating an example of a configuration of a pin according to a modification.

FIG. 12 is a cross-sectional view schematically illustrating an example of a configuration of a hole according to a modification.

FIG. 13 is a cross-sectional view schematically illustrating an example of a configuration of a pin according to another modification.

FIG. 14 is a cross-sectional view schematically illustrating an example of a configuration of a hole according to another modification.

FIG. 15 is a cross-sectional view schematically illustrating a spacer provided in a tray.

FIG. 16 is a cross-sectional view schematically illustrating another method of placing a wafer on a tray.

FIG. 17 is a cross-sectional view schematically illustrating another example of a configuration of a tray.

FIG. 18 is a cross-sectional view schematically illustrating another example of a configuration of a tray.

FIG. 19 is a cross-sectional view schematically illustrating another example of a configuration of a tray.

FIG. 20 is a cross-sectional view schematically illustrating another example of a configuration of a tray.

FIG. 21 is a cross-sectional view schematically illustrating another example of a configuration of a tray.

FIG. 22 is a cross-sectional view schematically illustrating an example of a state where a tray is placed on a substrate support.

FIG. 23 is a cross-sectional view schematically illustrating an example of a state where a tray is placed on a wafer loading and unloading stage.

FIG. 24 is a cross-sectional view schematically illustrating another example of a state where a tray is placed on the wafer loading and unloading stage.

FIG. 25 is a cross-sectional view schematically illustrating an example of a unit for supplying a liquid heat transfer material to a tray.

FIG. 26 is a timing chart illustrating a flow of a method of supplying the liquid heat transfer material to the tray.

FIG. 27 is a cross-sectional view schematically illustrating an example of a unit for supplying the liquid heat transfer material to the tray.

FIG. 28 is a side view schematically illustrating an example of an internal configuration of a tray stocker.

FIG. 29 is a plan view schematically illustrating an example of a configuration of a rack.

FIG. 30 is a side view schematically illustrating a state example of the rack.

FIG. 31 is a plan view schematically illustrating a state example of the rack.

FIG. 32 is a side view schematically illustrating another state example of the rack.

FIG. 33 is a plan view schematically illustrating another state example of the rack.

FIG. 34 is a flowchart illustrating an example of a configuration of a first wafer processing method.

FIG. 35 is a flowchart illustrating an example of a configuration of a second wafer processing method.

FIG. 36 is a view illustrating an example of a tray transfer method.

FIGS. 37A to 37C are cross-sectional views schematically illustrating an example of a method of fixing a tray to the substrate support.

FIGS. 38A to 38C are cross-sectional views schematically illustrating an example of a method of fixing a tray to the substrate support.

FIG. 39 is a view illustrating an example of sheath control using an electrostatic chuck.

FIG. 40 is a view illustrating an example of the sheath control using the electrostatic chuck.

FIG. 41 is a cross-sectional view schematically illustrating an example of a method of fixing a tray to the substrate support.

FIG. 42 is a perspective view illustrating an example of a configuration of a lock mechanism for fixing a tray to the substrate support.

FIG. 43 is a cross-sectional view schematically illustrating an example of a method of fixing a tray to the substrate support.

FIGS. 44A to 44B are cross-sectional views schematically illustrating an example of a method of fixing a tray to the substrate support.

FIG. 45 is a cross-sectional view schematically illustrating an example of a method of separating a tray from the substrate support.

FIG. 46 is a cross-sectional view schematically illustrating another example of a configuration of the substrate support.

FIG. 47 is a plan view schematically illustrating another example of a configuration of substrate support.

### DETAILED DESCRIPTION

In a process of manufacturing a semiconductor device, various kinds of plasma processing such as etching processing, film formation processing, and diffusion processing are performed on a semiconductor substrate (hereinafter, referred to as a “wafer”). In these kinds of plasma processing, it may be desirable to maintain a temperature of the wafer during the processing to be uniform in a surface of the wafer in order to obtain a uniform processing result in the surface. According to an aspect of the present disclosure, a substrate processing system is provided. The substrate processing system includes: a processing module configured to process a substrate; a vacuum transfer module connected to the processing module; an atmospheric transfer module connected to the vacuum transfer module via a load-lock module; and a transfer mechanism configured to transfer, to the processing module, the substrate and a tray on which the substrate is placed, in which the tray is formed with a recess provided in an upper surface of the tray and configured to accommodate the substrate, and a hole penetrating the tray from the recess to a lower surface of the tray, and the hole is configured to movably hold a pin configured to protrude from either the recess or the lower surface in a state where the pin is inserted into the hole.

According to the technique of the present disclosure, temperature uniformity in a surface of a substrate is appropriately improved during substrate processing.

According to the present disclosure, it is possible to appropriately improve temperature uniformity in a surface of the substrate during the substrate processing.

The inventors have observed that, in a substrate processing system, when a wafer to be subjected to substrate processing and an edge ring are attracted and held by a disk-shaped tray and are transferred to a process module, and plasma processing is performed in this state. For example, it may be required to prevent occurrence of temperature singularities at a contact point with a lift pin that transfers the tray to a susceptor or at an outer peripheral portion of the wafer that does not come into direct contact with the susceptor.

The technique according to the present disclosure has been made in consideration of the above-described circumstances, and appropriately improves temperature uniformity in a surface of a substrate during substrate processing. Hereinafter, a wafer processing system provided with a wafer processing module according to an embodiment will be described with reference to the drawings. The same reference numerals will be given to elements having substantially the same functional configurations throughout the specification and the drawings, and redundant description thereof will be omitted.

### <Wafer Processing System>

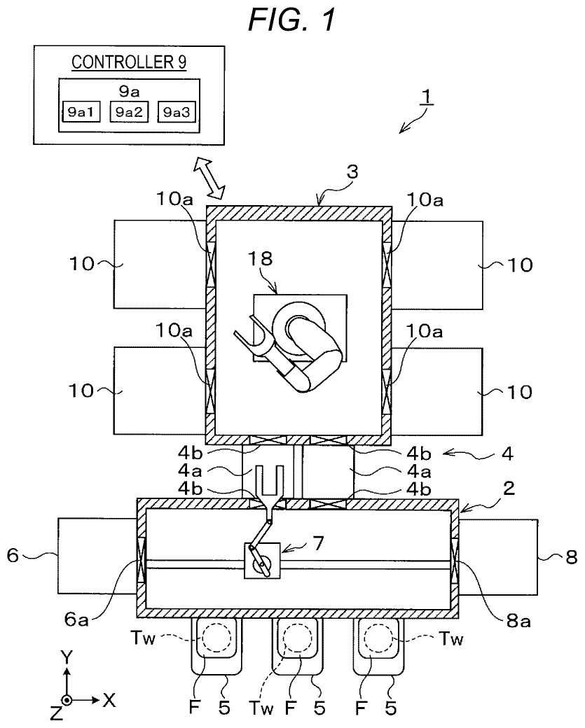

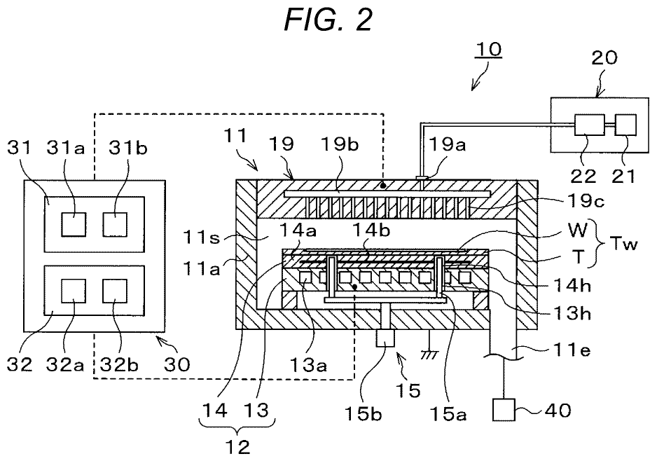

FIG. 1 is a plan view schematically illustrating an outline of a configuration of a wafer processing system 1. In the wafer processing system 1, various kinds of processing are performed on a wafer W that is a substrate. The wafer W is an example of a substrate. The wafer W is, for example, a semiconductor wafer such as a semiconductor substrate, and in one embodiment, a device layer that includes a plurality of devices is formed on a surface of the wafer W. In the wafer processing system 1 according to the present embodiment, the wafer W to be processed is transferred and processed in a state of being placed on a tray T to be described later (see FIG. 2). The wafer W is placed on the tray T in a state where the surface on which the device layer is formed faces upward. Hereinafter, for the sake of simplicity of description, the tray T in a first state of holding the wafer W to be transferred and processed in the wafer processing system 1 may be referred to as a “tray Tw”. A detailed configuration of the tray T will be described later.

In the following embodiment, a case where the device layer is formed on the surface of the wafer W as described above will be described as an example. However, the wafer W does not necessarily need to be a device wafer on which the device layer is formed.

As illustrated in FIG. 1, the wafer processing system 1 has a configuration in which an atmospheric transfer module 2 and a vacuum transfer module 3 are integrally connected to each other through a load-lock module 4. The atmospheric transfer module 2 transfers the wafer W, the tray T, or the tray Tw in an atmospheric environment. The vacuum transfer module 3 transfers the tray Tw in a vacuum (decompressed) environment.

The load-lock module 4 includes one or more load-lock chambers 4a, for example, two load-lock chambers 4a in the present embodiment. The load-lock chamber 4a is provided to enable communication between an interior space of the atmospheric transfer module 2 and an interior space of the vacuum transfer module 3 through a transfer port. The transfer port is configured to be openable and closable by a gate valve 4b.

The load-lock module 4 is configured to temporarily hold the tray Tw. The load-lock module 4 is configured such that an interior space thereof can be switched between an atmospheric environment and a decompressed environment (vacuum state). That is, the load-lock module 4 is configured to appropriately transfer the tray Tw between the atmospheric transfer module 2 in an atmospheric environment and the vacuum transfer module 3 in a decompressed environment.

The atmospheric transfer module 2 includes a rectangular housing therein, and an interior of the housing is maintained in the atmospheric environment. However, the atmospheric transfer module 2 can have any shape, and is not limited to a rectangular housing. A plurality of, for example, three load ports 5 are connected side by side on one side surface for forming a long side of the atmospheric transfer module 2 on a Y-axis negative direction side. The two load-lock chambers 4a described above are connected side by side on the other side surface (opposite to the one side surface) for forming a long side of the atmospheric transfer module 2 on a Y-axis positive direction side. An orienter module that adjusts a horizontal orientation of the wafer W, the tray T, or the tray Tw may be further connected to the atmospheric transfer module 2.

A tray stocker 6 serving as a storage module capable of storing a plurality of trays T is connected to the atmospheric transfer module 2 via an openable and closable shutter 6a. The tray stocker 6 according to the present embodiment is connected to the atmospheric transfer module 2. However, the present disclosure is not limited thereto. In one embodiment, the tray stocker 6 is connected to the vacuum transfer module 3. In another embodiment, the tray stocker 6 is provided outside the wafer processing system 1. Details of the tray stocker 6 will be described later.

A hoop F capable of storing a plurality of wafers W is placed in the load port 5. A ceiling transfer mechanism (OHT) movable along a rail disposed on a ceiling surface of a clean room where the wafer processing system 1 is disposed is provided above the wafer processing system 1, and the hoop F accesses the wafer processing system 1 via the ceiling transfer mechanism and is delivered to the load port 5.

Further, a first transfer mechanism 7 (e.g., transferer or first transferer) that transfers the wafer W, the tray T, or the tray Tw is provided in the atmospheric transfer module 2. The first transfer mechanism 7 is configured to transfer the tray Tw between the hoop F of the load port 5 and the load-lock chamber 4a of the load-lock module 4. A configuration of the first transfer mechanism 7 is not particularly limited.

The atmospheric transfer module 2 is provided with a wafer loading and unloading module 8 capable of loading and unloading the tray T and the wafer W therein. The wafer loading and unloading module 8 includes a wafer loading and unloading stage 200 to be described later. The wafer loading and unloading module 8 according to the present embodiment is connected to the atmospheric transfer module 2. However, the present disclosure is not limited thereto. In one embodiment, the wafer loading and unloading module 8 is connected to the vacuum transfer module 3. In another embodiment, the wafer loading and unloading module 8 is provided outside the wafer processing system 1.

The vacuum transfer module 3 is implemented by a planar rectangular housing, and an interior of the housing can be maintained in a vacuum (decompressed) environment. A plurality of, for example, four wafer processing modules 10 are connected to a side surface of the vacuum transfer module 3. An interior space of the wafer processing module 10 communicates with an interior space of the vacuum transfer module 3 through a transfer port. The transfer port is configured to be openable and closable by a gate valve 10a. The number and disposition of the wafer processing modules 10 are not limited to those in the present embodiment, and may be freely set.

Further, a second transfer mechanism 18 (e.g., transferer or second transferer)that transfers the tray Tw is provided in the vacuum transfer module 3. The second transfer mechanism 18 is configured to transfer the tray Tw between the load-lock chamber 4a of the load-lock module 4 and one or more wafer processing modules 10. A configuration of the second transfer mechanism 18 is not particularly limited.

In the wafer processing module 10 serving as a substrate processing apparatus, in an example, plasma processing such as etching processing is performed on the wafer W placed on the tray T. FIG. 2 is a view illustrating an example in which the wafer processing module 10 is a capacitively-coupled plasma processing apparatus.

The wafer processing module 10, which is a capacitively-coupled plasma processing apparatus, includes a plasma processing chamber 11, a gas supply 20, a power source 30, and an exhaust system 40. Further, the wafer processing module 10 includes a substrate support 12 and a gas introduction portion. The gas introduction portion is configured to introduce at least one processing gas into the plasma processing chamber 11. The gas introduction portion includes a shower head 19. The substrate support 12 is disposed in the plasma processing chamber 11. The shower head 19 is disposed above the substrate support 12. In one embodiment, the shower head 19 constitutes at least a portion of a ceiling portion of the plasma processing chamber 11. The plasma processing chamber 11 has a plasma processing space 11s defined by the shower head 19, a sidewall 11a of the plasma processing chamber 11, and the substrate support 12. The plasma processing chamber 11 is grounded. The shower head 19 and the substrate support 12 are electrically insulated from a housing of the plasma processing chamber 11.

The substrate support 12 includes a base 13, an electrostatic chuck 14, and a lifter 15. The base 13 includes a conductive member. The conductive member of the base 13 may function as a lower electrode. The electrostatic chuck 14 is disposed on the base 13. The electrostatic chuck 14 includes a ceramic member 14a and an electrostatic electrode 14b disposed in the ceramic member 14a. The ceramic member 14a is made of a dielectric and has a tray support surface for supporting the tray Tw. In one embodiment, the tray support surface of the ceramic member 14a has a larger diameter than the wafer W placed on the tray T, and a smaller diameter than the tray T or substantially the same size as the tray T.

At least one RF/DC electrode coupled to an RF power source 31 and/or a DC power source 32, which will be described later, may be disposed in the ceramic member 14a. In this case, at least one RF/DC electrode functions as the lower electrode. When a bias RF signal and/or DC signal, which will be described later, is supplied to at least one RF/DC electrode, the RF/DC electrode is also referred to as a bias electrode. The conductive member of the base 13 and the at least one RF/DC electrode may function as a plurality of lower electrodes. The electrostatic electrode 14b may also function as a lower electrode. Therefore, the substrate support 12 includes at least one lower electrode.

The lifter 15 includes a plurality of lift pins 15a, three lift pins 15a in the present embodiment, and an actuator 15b which is a driving mechanism that moves the lift pins 15a in a vertical direction. A plurality of through-holes 13h and 14h penetrating in a thickness direction are formed in the base 13 and the electrostatic chuck 14, and in the present embodiment, three through-holes 13h and 14h are formed, and the lift pins 15a of the lifter 15 are inserted into the through-holes 13h and 14h. Examples of the actuator 15b include an electric actuator, an air cylinder, and a motor.

Then, the lifter 15 causes the lift pins 15a to be moved along an axial direction (vertical direction) by the actuator 15b to lift and lower the tray Tw on the electrostatic chuck 14. Accordingly, the tray Tw is moved between a transfer height at which the transfer between the electrostatic chuck 14 and the second transfer mechanism 18 is performed and a processing height at which wafer processing is performed on the electrostatic chuck 14.

The substrate support 12 may include a temperature control module configured to adjust a temperature of at least one of the electrostatic chuck 14, the tray T, and the wafer W to a target temperature. The temperature control module may include a heater, a heat transfer medium, a flow path 13a, or a combination thereof. A heat transfer fluid, such as brine or gas, flows through the flow path 13a. In one embodiment, the flow path 13a is formed in the base 13, and one or a plurality of heaters are disposed in the ceramic member 14a of the electrostatic chuck 14. Further, the substrate support 12 may include a gas supply configured to supply a gas (for example, nitrogen (N₂) gas) to a gap between a back surface of the tray T and the tray support surface of the electrostatic chuck 14. This gas supply may be shared with the gas supply 20 to be described later.

The shower head 19 is configured to introduce at least one processing gas from the gas supply 20 into the plasma processing space 11s. The shower head 19 includes at least one gas supply port 19a, at least one gas diffusion chamber 19b, and a plurality of gas introduction ports 19c. A processing gas supplied to the gas supply port 19a passes through the gas diffusion chamber 19b and is introduced into the plasma processing space 11s from the gas introduction ports 19c. The shower head 19 includes at least one upper electrode. The gas introduction portion may include one or more side gas injectors (SGI) that are attached to one or more openings formed in the sidewall 11a, in addition to the shower head 19.

The gas supply 20 may include at least one gas source 21 and at least one flow rate controller 22. In one embodiment, the gas supply 20 is configured to supply at least one processing gas from each corresponding gas source 21 to the shower head 19 via each corresponding flow rate controller 22. The flow rate controller 22 may include, for example, a mass flow controller or a pressure-controlled flow rate controller. Further, the gas supply 20 may include at least one flow rate modulation device that modulates or pulses a flow rate of at least one processing gas.

The power source 30 includes the RF power source 31 coupled to the plasma processing chamber 11 via at least one impedance matching circuit. The RF power source 31 is configured to supply at least one RF signal (RF power) to at least one lower electrode and/or at least one upper electrode. Accordingly, plasma is formed from the at least one processing gas supplied to the plasma processing space 11s. Accordingly, the RF power source 31 may function as at least a part of the plasma generator. Supplying a bias RF signal to at least one lower electrode can generate a bias potential in the wafer W to attract an ionic component in the formed plasma to the wafer W.

In one embodiment, the RF power source 31 includes a first RF generator 31a and a second RF generator 31b. The first RF generator 31a is coupled to at least one lower electrode and/or at least one upper electrode via at least one impedance matching circuit, and is configured to generate a source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is coupled to the at least one lower electrode via the at least one impedance matching circuit and configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one lower electrode. In various embodiments, at least one of the source RF signal and the bias RF signal may be pulsed.

The power source 30 may include the DC power source 32 coupled to the plasma processing chamber 11. The DC power source 32 includes a first DC generator 32a and a second DC generator 32b. In one embodiment, the first DC generator 32a is connected to at least one lower electrode to generate a first DC signal. The generated first DC signal is applied to at least one lower electrode. In one embodiment, the second DC generator 32b is connected to at least one upper electrode and configured to generate a second DC signal. The generated second DC signal is applied to the at least one upper electrode.

In various embodiments, the first and second DC signals may be pulsed. In this case, a sequence of voltage pulses is applied to at least one lower electrode and/or at least one upper electrode. The voltage pulses may each have a rectangular, trapezoidal, or triangular pulse waveform or a combination thereof. In one embodiment, a waveform generator that generates the sequence of the voltage pulses from a DC signal is connected between the first DC generator 32a and at least one lower electrode. Accordingly, the first DC generator 32a and the waveform generator form a voltage pulse generator. When the second DC generator 32b and the waveform generator form a voltage pulse generator, the voltage pulse generator is connected to at least one upper electrode. The voltage pulse may have a positive polarity or a negative polarity. Further, the sequence of the voltage pulses may include one or more positive voltage pulses and one or more negative voltage pulses in one cycle. The first and second DC generators 32a and 32b may be provided in addition to the RF power source 31, and the first DC generator 32a may be provided instead of the second RF generator 31b.

The exhaust system 40 may be connected, for example, to a gas exhaust port 11e disposed at the bottom of the plasma processing chamber 11. The exhaust system 40 may include a pressure adjusting valve and a vacuum pump. The pressure adjusting valve adjusts pressure in the plasma processing space 11s. The vacuum pump may include a turbo molecular pump, a dry pump, or a combination thereof.

The wafer processing module 10 is configured as described above by way of example, but the configuration of the wafer processing module 10 is not limited thereto.

For example, in the example illustrated in FIG. 2, a case where a plasma generator of the wafer processing module 10 generates capacitively coupled plasma (CCP) has been described as an example. However, the plasma generated by the plasma generator may be inductively-coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 100 kHz to 150 MHz.

Referring back to the description of FIG. 1, the wafer processing system 1 described above includes a controller 9 as illustrated in FIG. 1. The controller 9 processes computer-executable instructions for causing the wafer processing system 1 to execute various steps described in the present disclosure. The controller 9 may be configured to control elements of the wafer processing system 1 to execute various steps described herein. In one embodiment, a part or all of the controller 9 may be provided in the wafer processing system 1. The controller 9 may include a processor 9a1, a storage 9a2, and a communication interface 9a3. The controller 9 is implemented by, for example, a computer 9a. The processor 9a1 may read a program from the storage 9a2 and execute various control operations by executing the read program. The program may be stored in advance in the storage 9a2, or may be acquired via a medium when necessary. The acquired program is stored in the storage 9a2, read from the storage 9a2 by the processor 9a1, and is executed. The medium may be various recording media readable by the computer 9a, or may be a communication line connected to the communication interface 9a3. The processor 9a1 may be a central processing unit (CPU). The storage 9a2 may include a random access memory (RAM), a read only memory (ROM), a hard disk drive (HDD), a solid state drive (SSD), or a combination thereof. The communication interface 9a3 may communicate with the wafer processing system 1 via a communication line such as a local area network (LAN). Further, the storage medium may be temporary or non-temporary medium. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

### <Tray>

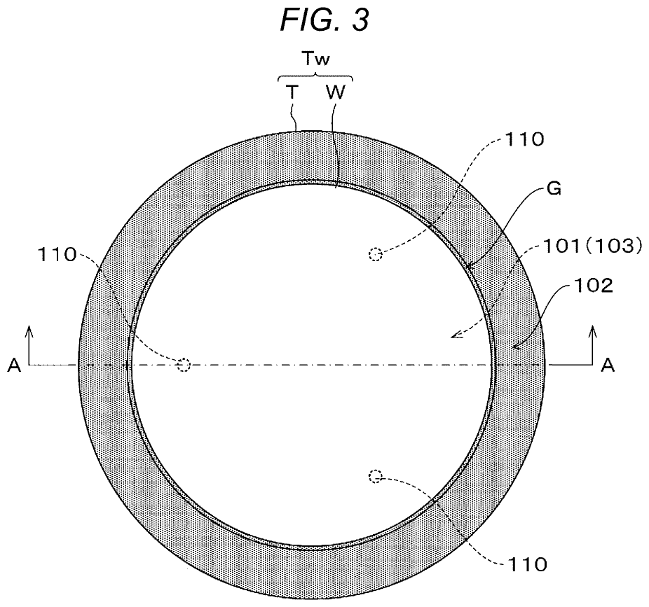

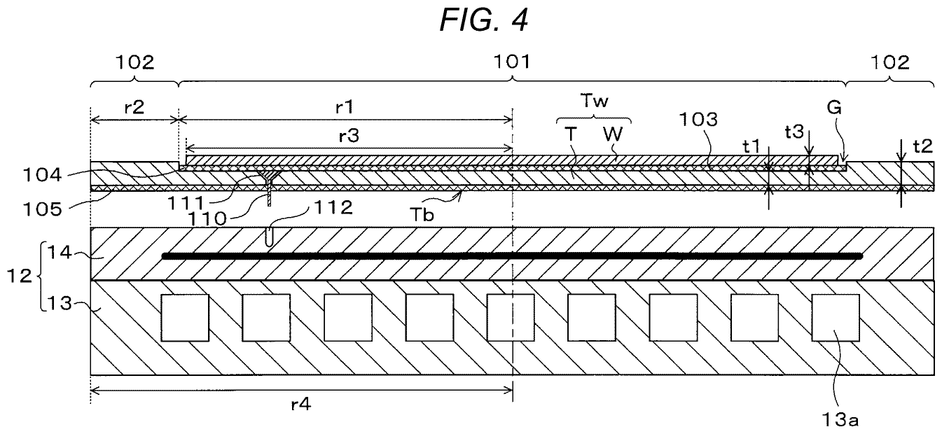

Next, a detailed structure of the tray T on which the wafer W is placed will be described. FIG. 3 is a plan view schematically illustrating an example of the configuration of the tray T viewed from above, and illustrates a state where the wafer W is placed on the tray T. FIG. 4 is a cross-sectional view taken along a line A-A in FIG. 3 which schematically illustrates an example of the configuration of the tray T, and illustrates a state where the tray T is disposed above the substrate support 12 in the wafer processing module 10. In FIG. 3, a dashed line indicates a line overlapping a diameter of the tray T, the tray T is shaded, and the wafer W placed on the tray T is illustrated in white. In FIG. 4, the through-holes 13h and 14h are omitted for the sake of simplicity of illustration.

As illustrated in FIGS. 3 and 4, the tray T has a substantially disk shape, and has a cross-sectional recess shape in which a thickness of a central portion is smaller than a thickness of an outer peripheral portion in a cross-sectional view. Hereinafter, the central portion of the tray T having a small thickness in a cross-sectional view will be referred to as a [disk portion 101], and the outer peripheral portion of the tray T having a large thickness in a cross-sectional view will be referred to as an [annular portion 102], for convenience. Further, a cross-sectional recess-shaped portion formed by the disk portion 101 and the annular portion 102 may be referred to as a “recess 103”. Further, the tray T has a first heat transfer material 104 disposed between the wafer W and an upper surface of the disk portion 101 when the wafer W is accommodated in the recess 103, and a second heat transfer material 105 disposed between a tray placing surface and a lower surface of the disk portion 101 when the tray T is placed on the tray placing surface of the electrostatic chuck 14.

As illustrated in FIGS. 3 and 4, pins 110 are provided at three positions of the recess 103 of the tray T. The pin 110 is held in a state of being inserted into a hole 111 provided in the recess 103 as illustrated in FIG. 4. The hole 111 is formed to penetrate the tray T from the recess 103 to a lower surface Tb of the tray T. Further, a pin receiving hole 112 is provided at a position corresponding to the pin 110 on an upper surface of the electrostatic chuck 14.

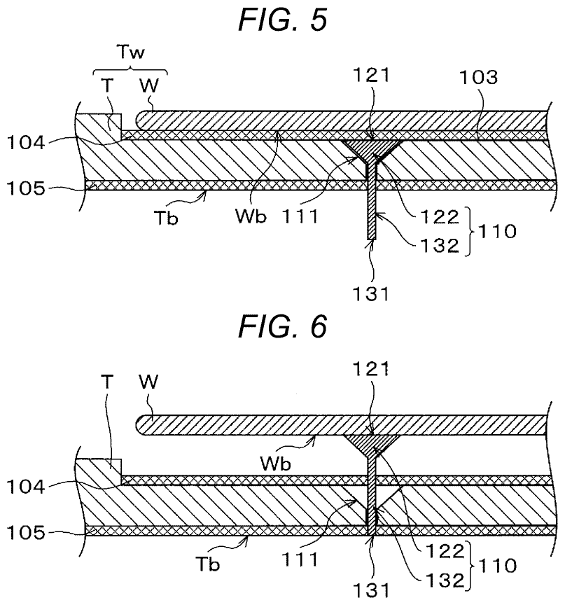

FIGS. 5 and 6 are partial cross-sectional views illustrating a schematic configuration of the pin 110 and the hole 111 in the tray T. FIG. 5 illustrates a first state where the wafer W is accommodated in the recess 103 of the tray T. FIG. 6 illustrates a second state including a transition state where the tray T and the wafer W are loaded and unloaded.

In FIG. 5, the pin 110 includes a head 122 having an upper end 121 of the pin 110 and a base 132 having a lower end 131 of the pin 110. In the first state where the wafer W is accommodated in the recess 103 of the tray T, the recess 103 of the tray T and a back surface Wb of the wafer W are in contact with each other via the first heat transfer material 104. In the first state, the upper end 121 of the pin 110 does not protrude from the recess 103, and the lower end 131 protrudes from the lower surface Tb of the tray T.

In FIG. 6, the recess 103 of the tray T and the back surface Wb of the wafer W are spaced apart from each other, and the tray T and the wafer W are separated from each other, in the second state including the transition state where the tray T and the wafer W are loaded and unloaded. The second state includes a state where the upper end 121 of the pin 110 is in contact with the back surface Wb of the wafer W and protrudes from the recess 103, and the lower end 131 does not protrude from the lower surface Tb of the tray T. In the present embodiment, the lower surface Tb of the tray T refers to a lower surface of the second heat transfer material 105. That is, the second state according to the present embodiment includes a state where the base 132 does not protrude from the lower surface of the second heat transfer material 105. In the present specification, “loading and unloading” refers to the transition between a state where the wafer W is accommodated in the recess 103 of the tray T and a state where the tray T and the wafer W are separated from each other. Further, the term “loaded and unloaded” refers to a case where the wafer W is operated to be accommodated in the recess 103 of the tray T and a case where the wafer W is operated to be separated from the tray T. In the second state according to one embodiment, the tray T and the wafer W are loaded and unloaded in a state where the lower end 131 of the pin 110 protrudes from the lower surface Tb of the tray T. As an example, the base 132 of the pin 110 is sufficiently long, and the lower end 131 of the pin 110 is held in a state of protruding from the lower surface Tb of the tray T on a substrate loading and unloading portion to be described later, and the upper end 121 of the pin 110 protrudes from the recess 103 in this state, thereby loading and unloading the tray T and the wafer W.

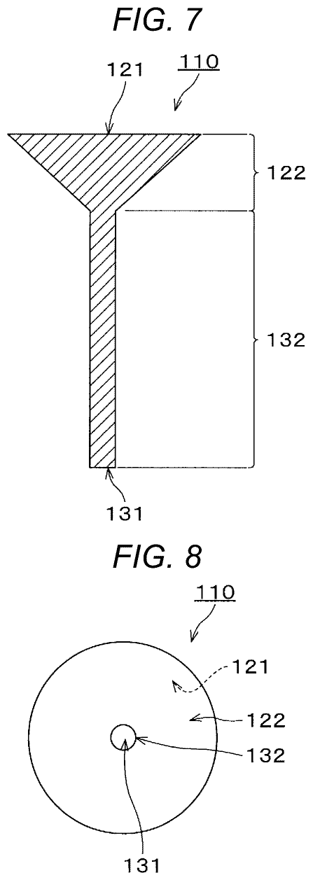

FIG. 7 is a cross-sectional view schematically illustrating a configuration of the pin 110 according to the present embodiment. FIG. 8 is a plan view schematically illustrating a configuration of the pin 110 according to the present embodiment as viewed from the lower end 131. The pin 110 according to the present embodiment includes the head 122 and the base 132 as described above. The head 122 has a substantially conical shape with an upper end surface including the upper end 121 serving as a bottom surface. The base 132 is connected to an apex portion of the conical shape. The base 132 has a substantially cylindrical shape with a lower end surface including the lower end 131 serving as a bottom surface.

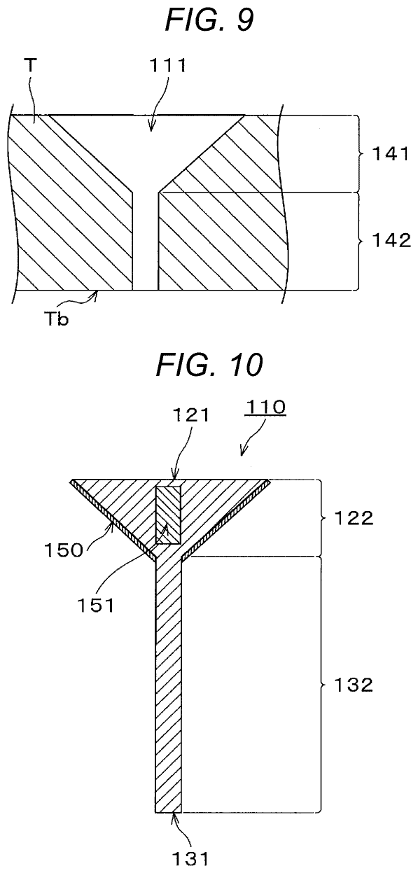

FIG. 9 is a cross-sectional view schematically illustrating a configuration of the hole 111, into which the pin 110 illustrated in FIGS. 7 and 8 is inserted, in the recess 103 of the tray T. The hole 111 according to the present embodiment has an inner diameter slightly larger than an outer diameter of the entire head 122 of the pin 110 and a part of the base 132, so that the pin 110 can be inserted into the hole 111. That is, as illustrated in FIG. 9, the hole 111 includes a head receiving portion 141 and a base receiving portion 142 which form an inner surface of the hole 111. The head receiving portion 141 has an inner diameter slightly larger than an outer diameter of an outer surface of the head 122 of the pin 110. The base receiving portion 142 has an inner diameter dimension slightly larger than an outer diameter dimension of an outer surface of the base 132.

According to the pin 110 and the hole 111 as illustrated in FIGS. 7 to 9, an outer surface of the pin 110 and an inner surface of the hole 111 are in contact with each other without a gap in the first state. Here, the term “in contact with each other without a gap” indicates, as an example, that when the first heat transfer material 104 is a liquid heat transfer material to be described later, the outer surface of the pin 110 and the inner surface of the hole 111 are in contact with each other without a gap to an extent that the liquid heat transfer material does not leak from a portion where the outer surface of the pin 110 and the inner surface of the hole 111 are in contact with each other.

In one embodiment, the tray T may be manufactured in which the outer surface of the pin 110 and the inner surface of the hole 111 are in contact with each other without a gap by cutting a part of the tray T by discharge machining. According to the discharge machining, a part of the tray T can be cut to form the hole 111, and at the same time, the part of the cut tray T can be used as a part of the pin 110.

In one embodiment, as illustrated in FIG. 10, the head 122 of the pin 110 includes a seal 150 at a portion of the head 122 corresponding to a side surface when the head 122 is viewed as a cone. The seal 150 forms a part of the outer surface of the pin 110, and is formed such that the outer surface of the pin 110 and the inner surface of the hole 111 are in contact with each other without a gap. Further, a core 151 is embedded in the head 122.

The seal 150 is, for example, a water-repellent film or an oil-repellent film formed on a side surface of the pin 110 by atomic layer deposition (ALD), or is subjected to water-repellent processing or oil-repellent processing. In this example, the seal 150 is formed to have a thickness of several nm. As another example, the seal 150 is an elastic thin film formed on the side surface of the pin 110.

The core 151 is a material having a relatively large specific gravity, for example, a metal, and is a member that increases the weight of the entire pin 110. As an example, the core 151 is made of tungsten. A location where the core 151 is embedded is not limited to this example, and, for example, may be embedded in the base 132.

In the present embodiment, the pin 110 preferably has substantially the same linear expansion coefficient or heat conductivity as the tray T. As an example, the pin 110 is made of the same material as the tray T.

In the tray T having the configuration described above, the pin 110 is movably held to protrude from either the recess 103 or the lower surface Tb of the tray T in a state where the pin 110 is inserted into the hole 111. In other words, the base 132 of the pin can move in an up-down direction in the base receiving portion 142. Further, the head 122 of the pin 110 is held by the head receiving portion 141 of the hole 111, thereby locking the pin 110 by a force from the recess 103 toward the lower surface Tb of the tray T so that the pin 110 does not come out from the hole 111. Here, as an example, the force to the pin 110 from the recess 103 to the lower surface Tb of the tray T is gravity.

### <Modifications of Tray>

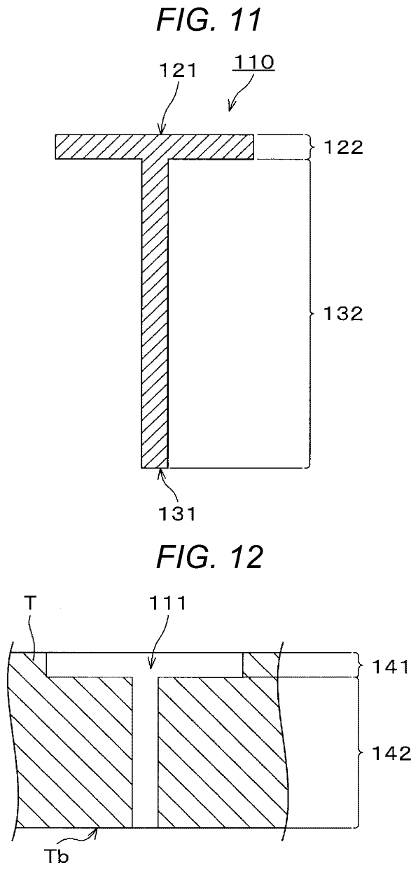

The pin 110 and the hole 111 in the tray T according to the present embodiment are configured as described above. However, the present disclosure is not limited to this example. Hereinafter, configurations of the pin 110 and the hole 111 in the tray T according to modifications of the present embodiment will be described with reference to FIGS. 11 to 14.

In a first modification, the pin 110 includes the flat substantially cylindrical head 122 with an upper end surface serving as a bottom surface as illustrated in FIG. 11. As illustrated in FIG. 12, the hole 111 has the head receiving portion 141 having a shape corresponding to the head 122 of the pin 110 illustrated in FIG. 11.

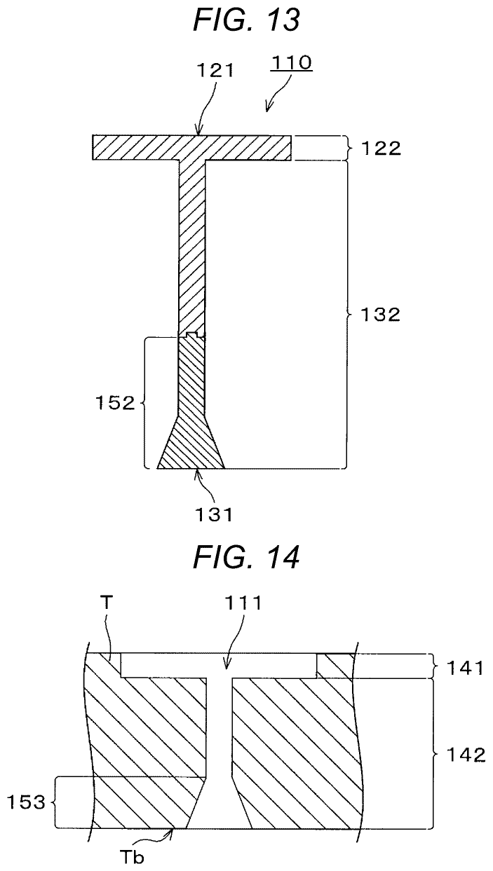

In a second modification, the pin 110 includes the head 122 having the same shape as that in the first modification, as illustrated in FIG. 13. Further, the base 132 includes a locking portion 152. The locking portion 152 has a portion with a diameter larger than a diameter of at least a portion of the base 132 excluding the locking portion 152. In the illustrated example, the lower end 131 is included in the locking portion 152. The locking portion 152 includes a substantially conical portion with the lower end 131 serving as a bottom surface. The locking portion 152 may be provided separately from the head 122 and a portion of the base 132 excluding the locking portion 152. In this case, the locking portion 152 may be formed by a different material. The entire base 132 may be provided as the locking portion 152. Further, as illustrated in FIG. 14, the hole 111 has a locking portion receiving portion 153 having a shape corresponding to the locking portion 152 of the pin 110 illustrated in FIG. 13. In the example illustrated in FIGS. 13 and 14, a portion of the pin 110 excluding the locking portion 152 is inserted into the hole 111 from above. Further, the locking portion 152 of the pin 110 is inserted into the hole 111 from below. Accordingly, the pin 110 is assembled by engaging the portion of the pin 110 excluding the locking portion 152 with the locking portion 152. Accordingly, the base 132 of the pin can be moved in the up-down direction in the base receiving portion 142, and can be locked so as not to be moved upward after the locking portion 152 comes into contact with the locking portion receiving portion 153. That is, the pin 110 is locked by a force to the pin 110 from the lower surface Tb of the tray T to the recess 103 so that the pin 110 does not come out from the hole 111. Here, as an example, the force to the pin 110 from the lower surface Tb of the tray T to the recess 103 may be a surface tension force or the like that acts to adsorb an upper end surface to the wafer W when the wafer W and the upper end surface of the pin 110 are in contact with each other via a liquid. In this case, when the wafer W is lifted upward, a force may be further applied to the pin 110 such that the wafer W is lifted in accordance with the surface tension force. Even in this case, according to the locking portion 152 in the second modification, the pin 110 does not come out from the hole 111. The locking portion 152 has a substantially conical shape. However, the locking portion 152 is not limited thereto as long as the pin 110 does not come out from the hole 111. For example, the locking portion 152 may have a substantially cylindrical shape having a diameter larger than a diameter of a portion of the base 132 excluding the locking portion 152.

The configuration of the pin 110 and the hole 111 according to the present embodiment including the modifications can be combined in accordance with a preferable aspect. That is, in the first modification and the second modification, the seal 150 may be formed on a side surface of the head 122. The seal 150 may be formed on a bottom surface of the head 122 that faces an upper end surface. Further, the core 151 may be embedded in the head 122 or the base 132. In addition to the second modification, the base 132 may be provided with the locking portion 152.

Referring back to FIG. 4, the disk portion 101 is made of, for example, at least one material selected from Si, SiC, SiN, C, SiO₂, Al₂O₃, Y₂O₃, YOF, W, Ti, TiN, ZrO₂, and a green sheet. Accordingly, the disk portion 101 may be made of a conductive material or may be made of an insulating material. Further, the relative permittivity of the disk portion 101 may be 8.0 or less. A volume resistivity of the disk portion 101 may be, for example, 1×10e12 [Ω·cm] or less when the electrostatic chuck 14 is a Johnson-Rahbek (JR) type electrostatic chuck, or may be 1×10e13 [Ω·cm] or more when the electrostatic chuck 14 is a Coulomb type electrostatic chuck.

In FIG. 4, a diameter r1 of the disk portion 101 is formed to be slightly larger than a diameter r3 of the wafer W, and the wafer W can be accommodated in the disk portion 101. Accordingly, the disk portion 101 of the tray T has a wafer placing surface for supporting the wafer W, and the tray T has the recess 103 for accommodating the wafer W. When the wafer W is placed on the wafer placing surface, a gap G (a difference between the diameter r1 and the diameter r3) generated between an outer end portion of the wafer W and an inner peripheral surface of the annular portion 102 is preferably 0.1 mm or less. In order to efficiently cool the wafer W to be described later, the diameter r1 of the disk portion 101 is preferably equal to or less than a diameter r4 of the substrate support 12 (the electrostatic chuck 14) that holds the tray Tw in the wafer processing module 10.

A thickness t1 of the disk portion 101 is not particularly limited, and is preferably set to a thickness that can efficiently cool the wafer W to be described later and can ensure a mechanical strength of the tray T.

The annular portion 102 is made of, for example, at least one material selected from Si, SiC, SiN, C, SiO₂, Al₂O₃, Y₂O₃, YOF, W, Ti, TiN, ZrO₂, and a green sheet, and may be made of the same material as the disk portion 101, or may be made of a different material. Accordingly, the annular portion 102 may be made of a conductive material or may be made of an insulating material. However, in a case where the annular portion 102 is used as an edge ring in plasma processing to be described later, the annular portion 102 may be made of a material equivalent to an edge ring in the related art. Further, it is preferable that the relative permittivity and the volume resistivity of the annular portion 102 are the same as those of the wafer W.

A thickness t2 of the annular portion 102 can be appropriately changed according to the purpose of wafer processing. Accordingly, an upper surface height of the annular portion 102 may be larger than, smaller than, or the same as an upper surface height of the wafer W. The thickness t2 of the annular portion 102 is, for example, 3 mm to 5 mm. During plasma processing in the wafer processing module 10, the annular portion 102 is disposed in a manner of surrounding the periphery of the wafer W held on the disk portion 101, and also functions as an edge ring (also referred to as a focus ring) for reducing non-uniformity of the plasma processing. Accordingly, the thickness t2 and a width r2 of the annular portion 102 may be substantially the same as a thickness and a width of an edge ring used in plasma processing in the related art.

A diameter of the entire tray T (that is, an outer diameter of the annular portion 102, diameter r1+width r2) may be equal to or larger than the diameter r4 of the substrate support 12 (the electrostatic chuck 14) that holds the tray Tw in the wafer processing module 10 (diameter r1+width r2≥diameter r4). In this case, it is possible to prevent a surface of the substrate support 12 (the electrostatic chuck 14) from being exposed to plasma during the plasma processing in the wafer processing module 10 by making the tray T larger than the substrate support 12. Accordingly, it is possible to reduce consumption of the substrate support 12 and reduce a time and a frequency required for maintenance of the wafer processing module 10.

As described above, the gap G is formed between an outer end portion of the wafer W and an inner peripheral surface of the annular portion 102. In a portion where the gap G is formed, corners of the recess 103 may be exposed to plasma during plasma processing in the wafer processing module 10. In this case, the corners are easily consumed depending on a material of the tray T, which may cause deterioration in life of the tray T or generation of particles. It is known that consumption of a corner easily occurs when a shape of the corner is a right angle.

Therefore, in order to prevent consumption of the corners of the recess 103, the corners may not be formed at a right angle, and a space between the wafer W and the tray T may be filled. Specifically, for example, as illustrated in FIG. 15, it is preferable to provide a round-shaped spacer 106 at a corner 103a of the recess 103. A spacer configured to match a shape of an outer end portion of the wafer W may be provided instead of the round-shaped spacer. In this case, the spacer 106 is formed of a member having at least plasma resistance. By providing the spacer 106 at the corner 103a in this manner, it is possible to prevent the corner 103a from being exposed to plasma during the plasma processing in the wafer processing module 10, and prevent deterioration of life of the tray T and generation of particles.

The spacer 106 disposed in the corner 103a may be integrally formed with at least one of the disk portion 101 and the annular portion 102, instead of being formed as a separate body from the tray T (the disk portion 101 and the annular portion 102) as illustrated in FIG. 15.

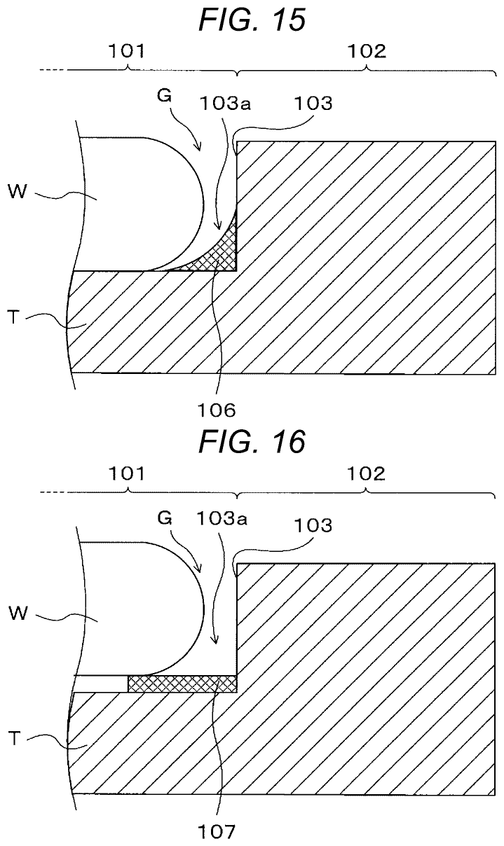

In the examples illustrated in FIGS. 4 and 15, the wafer W is held on the disk portion 101 of the tray T. However, as illustrated in FIG. 16, a stepped portion 107 for holding an outer peripheral portion of the wafer W may be provided at the annular portion 102 to hold the wafer W on the stepped portion 107. Instead of the stepped portion 107, the wafer W may be held on the spacer 106 illustrated in FIG. 15. In other words, the spacer 106 may have a rectangular cross-sectional shape, and may have the stepped portion 107 for holding the outer peripheral portion of the wafer W. In this case, a gap is formed between the back surface of the wafer W and the disk portion 101 of the tray T. However, the wafer W can be properly cooled as will be described later by filling the gap with the first heat transfer material 104 to be described later.

In FIG. 4, a case is illustrated where the disk portion 101 and the annular portion 102 of the tray T are integrally formed using the same material by way of example. However, the configuration of the tray T is not limited thereto.

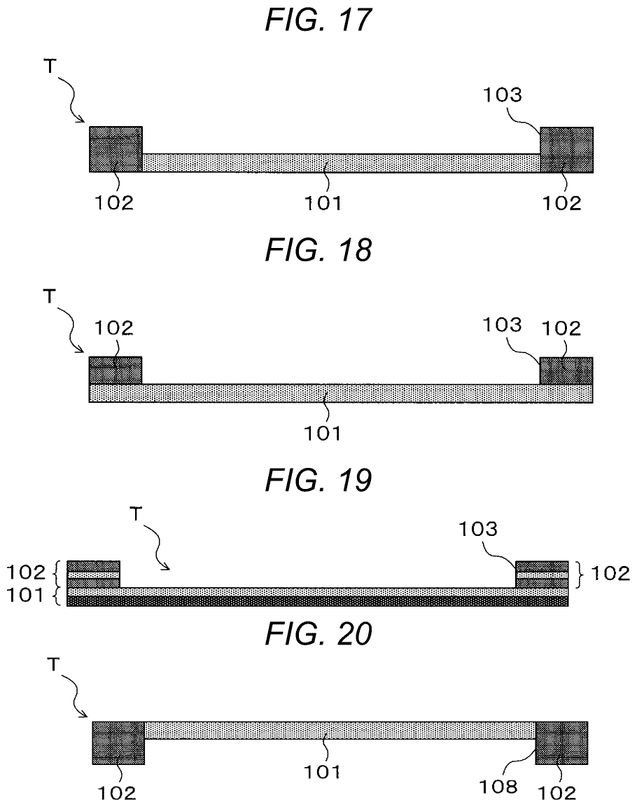

Specifically, for example, instead of integrally forming the disk portion 101 and the annular portion 102 as illustrated in FIG. 4, the tray T may be formed by separately forming the disk portion 101 and the annular portion 102 and attaching the disk portion 101 and the annular portion 102 to each other. In this case, the disk portion 101 and the annular portion 102 may be bonded to each other using, for example, an adhesive sheet or an adhesive, or may be mechanically or chemically bonded to each other. Further, the disk portion 101 and the annular portion 102 may be made of different materials as illustrated in FIG. 17, or may be made of the same material.

In FIGS. 4 and 17, a case is illustrated where the annular portion 102 surrounds the periphery of the disk portion 101, that is, the diameter r1 of the disk portion 101 is the same as an inner diameter of the annular portion 102 by way of example. However, as illustrated in FIG. 18, the tray T may be configured such that the diameter r1 of the disk portion 101 and the outer diameter of the annular portion 102 are the same and the annular portion 102 is disposed on an upper surface of the disk portion 101. In this case, the disk portion 101 has a placing surface (ring placing surface) for the annular portion 102 serving as an edge ring on an upper surface of the disk portion 101. The disk portion 101 and the annular portion 102 may also be made of the same material in this case. Further, in this case, an edge ring in the related art may be used as the annular portion 102.

In FIGS. 4, 17, and 18, the disk portion 101 and the annular portion 102 are each formed by a single member. However, at least one of the disk portion 101 and the annular portion 102 may be formed by stacking two or more members as illustrated in FIG. 19. In this case, each of a plurality of members to be stacked may be made of a different material as illustrated in FIG. 19, or the members may be made of the same material.

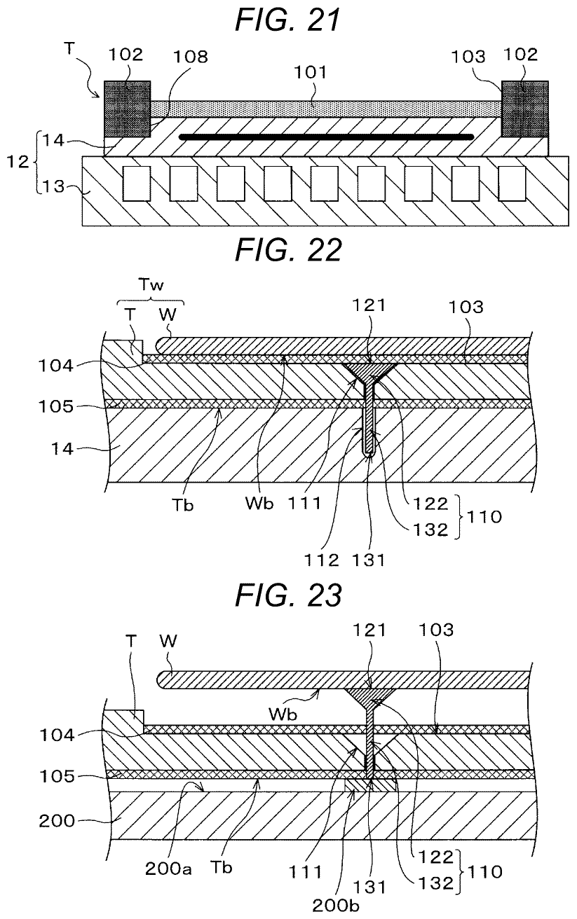

Further, in FIG. 4 and FIGS. 17 to 19, a case is illustrated where the recess 103 is formed on an upper surface side (wafer placing surface) of the tray T. However, instead of or in addition to this, as illustrated in FIGS. 20 and 21, a recess 108 may be further formed on a lower surface side of the tray T. In this case, it is preferable that the recess 108 formed on the lower surface side of the tray T have a shape that engages with a tray support surface of the electrostatic chuck 14, as illustrated in FIG. 21.

The first heat transfer material 104 is disposed between the wafer W and the wafer placing surface of the tray T as illustrated in FIG. 4. Accordingly, the first heat transfer material 104 is disposed in the recess 103 of the tray T. The first heat transfer material 104 may adopt a liquid heat transfer material or a heat transfer sheet as will be described later. The wafer W placed on the tray T is in full thermal contact with the tray T via the first heat transfer material 104, so that cooling efficiency of the wafer W by the heat transfer fluid flowing through the flow path 13a formed in the base 13 can be improved.

More specifically, in a plasma processing apparatus in the related art, in order to prevent a surface of an electrostatic chuck from being exposed to plasma and from being consumed, a wafer placing surface of the electrostatic chuck is generally smaller than a wafer to be held (a diameter of the wafer >an outer diameter of the electrostatic chuck). However, in this case, an outer peripheral portion of the wafer is not directly held by the electrostatic chuck, and as a result, cooling of the outer peripheral portion may be insufficient as compared with a central portion of the wafer.

For example, in a case where the wafer W is deformed due to warpage, it becomes difficult to make the electrostatic chuck and the entire surface of the wafer in solid contact uniformly, and as a result, a pressing force on the electrostatic chuck is weakened in a part (a portion warped and deformed upward) of the surface of the wafer, and thus, cooling may be insufficient in a part of the surface of the wafer.

In this respect, as in the technique according to the present embodiment, by accommodating the wafer W in the recess 103 of the tray T, and further providing the first heat transfer material 104 between the wafer W and the disk portion 101 of the tray T, the wafer W and the tray T can be easily brought into full contact with each other via the first heat transfer material 104, so that the entire surface of the wafer W can be uniformly cooled.

For example, a liquid heat transfer material or a heat transfer sheet can be selected as the first heat transfer material 104. However, as long as heat transfer efficiency between the wafer W and the tray T can be improved by appropriately bringing the wafer W and the tray T into full contact with each other, a gas may be used as the first heat transfer material 104. Details of the liquid heat transfer material and the heat transfer sheet will be described later.

The second heat transfer material 105 is disposed between the tray T and the tray placing surface of the electrostatic chuck 14 as illustrated in FIG. 4. The second heat transfer material 105 may adopt a liquid heat transfer material or a heat transfer sheet as will be described later. The second heat transfer material 105 may use the same material as the first heat transfer material 104, or may use a different material. The tray T held by the electrostatic chuck 14 is in full thermal contact with the electrostatic chuck 14 via the second heat transfer material 105, so that the cooling efficiency of the tray T by a heat transfer fluid flowing through the flow path 13a formed in the base 13 can be improved, and thus the cooling efficiency of the wafer W placed on the tray T can be improved.

More specifically, in a plasma processing apparatus in the related art, in order to sufficiently cool a wafer on an electrostatic chuck, for example, it is necessary to increase a pressing force of the wafer against a wafer placing surface of the electrostatic chuck by an electrostatic force or the like, and properly maintain a solid contact between the electrostatic chuck and the wafer.

In this respect, as in the technique according to the present embodiment, by providing the second heat transfer material 105 between the tray T and the tray support surface of the electrostatic chuck 14, the tray T and the electrostatic chuck 14 are easily brought into thermal contact with each other via the second heat transfer material 105, and a sufficient cooling effect of the wafer W can be expected by the weight of the tray Tw without applying a stress such as electrostatic attraction. The wafer W can be cooled by the weight of the tray Tw by interposing the second heat transfer material 105 in this manner. However, the tray T may be held on the electrostatic chuck 14 by electrostatic attraction or the like. In this case, a pressing force of the tray T against the electrostatic chuck 14 can be improved, and the cooling efficiency of the wafer W can be further improved.

As illustrated in FIGS. 4 and 22, the electrostatic chuck 14 is provided with the pin receiving hole 112. In a state where the tray Tw in the first state is placed on the electrostatic chuck 14, the base 132 protruding from the lower surface Tb of the tray T is inserted into the pin receiving hole 112 provided in the electrostatic chuck 14. Accordingly, in a state where the tray Tw in the first state is placed on the electrostatic chuck 14, the lower end 131 of the base 132 comes in contact with the electrostatic chuck 14 and the pin 110 is not pushed upward.

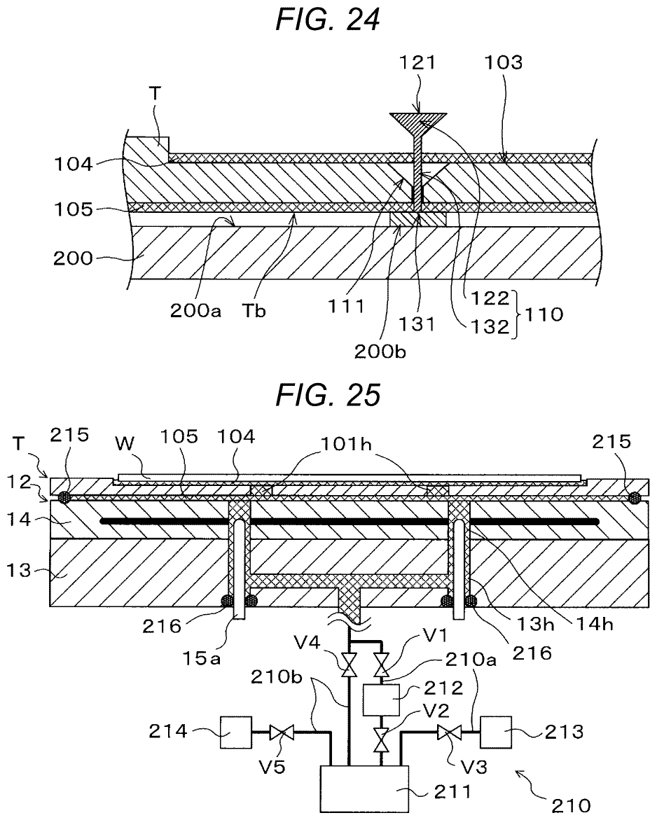

As illustrated in FIGS. 6 and 23, in the second state including the transition state where the wafer W and the tray T are loaded and unloaded, the tray T (tray Tw) is placed on the wafer loading and unloading stage 200 serving as a substrate loading and unloading portion according to the present embodiment. The wafer loading and unloading stage 200 according to the present embodiment is provided in the wafer loading and unloading module 8. In FIGS. 23 and 24, the second heat transfer material 105 may not be provided on the wafer loading and unloading stage 200 on which the tray T and the wafer W are loaded and unloaded.

When the tray Tw in the first state is placed on the wafer loading and unloading stage 200, the lower end 131 of the pin 110 protruding from the lower surface Tb of the tray T first comes into contact with a stage scaffolding 200b provided on an upper surface 200a of the wafer loading and unloading stage 200. The stage scaffolding 200b is a substantially cylindrical portion provided at a position corresponding to the pin 110 in the tray T and protruding from the upper surface 200a of the wafer loading and unloading stage 200. Subsequently, in this state, the lower surface Tb of the tray T is lowered until the lower surface Tb comes into contact with the stage scaffolding 200b of the wafer loading and unloading stage 200, so that the base 132 of the pin 110 is moved upward relative to the base receiving portion 142 and acts to push the wafer W upward. Accordingly, in a state where the lower surface Tb of the tray T is in contact with the stage scaffolding 200b of the wafer loading and unloading stage 200, the wafer W is separated from the recess 103 of the tray T in a state where the wafer W is placed on the upper end 121 of the pin 110.

As illustrated in FIG. 24, in a third state where the tray T is placed on the wafer loading and unloading stage 200 when the wafer W is not placed on and is not loaded and unloaded from the tray T, the upper end 121 of the pin 110 protrudes from the recess 103 by the action of the pin 110 and the hole 111 as described above, and the lower end 131 of the pin 110 does not protrude from the lower surface Tb of the tray T. For the tray T in the third state, the wafer W is transferred above the tray T by a desired transfer device, and then the wafer W is lowered to be placed such that a back surface Wb comes into contact with the upper end 121 of the pin 110. Specifically, the wafer W can be lowered by moving the tray T in a reverse order to a case where the wafer W is separated from the tray T. That is, by lifting the tray T, the base 132 of the pin 110 is moved downward relative to the base receiving portion 142 and acts to lower the wafer W downward during the lower end 131 of the pin 110 is separated from the stage scaffolding 200b of the wafer loading and unloading stage 200. Thereafter, the back surface Wb of the wafer W comes into contact with the recess 103 of the tray T, so that the wafer W is accommodated in the recess 103. At this time, the pin 110 is locked and held by bringing the head 122 into contact with the head receiving portion 141. The third state according to one embodiment is a state where the lower end 131 of the pin 110 protrudes from the lower surface Tb of the tray T. As an example, the base 132 of the pin 110 is sufficiently long, the lower end 131 of the pin 110 is fitted in a recess provided at a corresponding position of the stage scaffolding 200b, and is held in a state of protruding from the lower surface Tb of the tray T, and the upper end 121 of the pin 110 protrudes from the recess 103 in this state, thereby setting the tray T in the third state.

As an example, the wafer loading and unloading stage 200 serving as a substrate loading and unloading portion according to the present embodiment may be an electrostatic chuck configured to be electrostatically attracted to the tray T by an electrostatic force. The tray T may be configured to be attracted by a magnetic force by providing a member of a ferromagnetic material and/or at least one permanent magnet at positions corresponding to the wafer loading and unloading stage 200 and the annular portion 102 of the tray T. Further, the annular portion 102 of the tray T may be configured to be pushed down by a transfer arm 7a to be described later, thereby pressing the annular portion 102 against the wafer loading and unloading stage 200.

As long as the functions and effects described above are achieved, dimensions of the pin 110 and the hole 111 may be determined as desired depending on the purpose and usage of the tray T, a type of processing performed on the wafer W, a type of the first heat transfer material 104 and the second heat transfer material 105, and the like. In one embodiment, an upper end surface of the pin 110 including the upper end 121 of the head 122 has a diameter of 2.0 mm or more and 5.0 mm or less. A lower end surface of the base 132 including the lower end 131 has a diameter of 0.5 mm or more and less than 2.0 mm.

The tray T according to the present embodiment is configured as described above by way of example. According to the present embodiment, the annular portion 102 functioning as an edge ring in the related art is transferred together with the wafer W as described above. In other words, the edge ring (annular portion 102) and the wafer W are integrally unloaded from the wafer processing module 10 in one processing of the wafer processing module 10. Accordingly, when the edge ring (the annular portion 102) is consumed by the plasma processing, it is not necessary to stop the operation of the wafer processing module 10 for replacing the edge ring as in the related art, and the annular portion 102 unloaded from the wafer processing module 10 in one processing may be replaced directly outside the wafer processing module 10. Accordingly, it is possible to maximize an operating time of the wafer processing module 10.

Further, since the edge ring (annular portion 102) is replaced in one processing in this manner, consumption of the edge ring due to continuous wafer processing in the wafer processing module 10 is prevented, and as a result, an influence on a process result due to the consumption of the edge ring is prevented.

In this manner, the tray T consumed by the plasma processing may be reconditioned and regenerated only for the consumed portion after the tray T is unloaded from the wafer processing module 10, then the tray T may be reloaded with the wafer W and transferred to the wafer processing module 10. For example, the consumed portion may be reconditioned and regenerated by thermal spraying, or may be reconditioned and regenerated by CVD, PVD, sol-gel, or stacking molding technique (3D printing technique). Alternatively, after the tray T is subjected to coarse separation and surface layer blasting and separated for each constituent material, the tray T may be reused as a new processed product different from the tray T. Si powder obtained through the separation may be used for the reconditioning and regeneration of the consumed portion of the tray T described above after the powder is formed.

### <Liquid Heat Transfer Material>

Next, details of a liquid heat transfer material used as the first heat transfer material 104 and/or the second heat transfer material 105 will be described.

When a liquid heat transfer material is used as the first heat transfer material 104 and/or the second heat transfer material 105, a material that does not volatilize under at least vacuum (reduced pressure) and has high thermal conductivity is selected as the liquid heat transfer material. An example of the liquid heat transfer material is a low vapor pressure liquid, and can be selected from any one of an ionic liquid, a silicone oil (silicon liquid), and a fluorinated oil.

The ionic liquid is an ionic compound that is a liquid at room temperature, and is also referred to as a room temperature molten salt. The ionic liquid has characteristics such as almost zero vapor pressure and non-volatility (does not volatilize even at a high temperature or in a vacuum). The ionic liquid contains positively charged ions (cations) and negatively charged ions (anions).

Examples of the cations constituting the ionic liquid include nitrogen-containing cations such as a pyridinium-type, an imidazolium-type, an ammonium-type, a pyrrolidinium-type, a piperidinium-type, and phosphorus-containing cations such as a phosphonium-type. These cations contain an alkyl group such as —(CH₂)ₙCH₃ as a side chain. Other examples of the cations constituting the ionic liquid include a morpholinium-type and a sulfonium-type.

Examples of anions constituting the ionic liquid include TfO⁻, Tf2N⁻(TFSA⁻), Tf3C⁻, FSA⁻, CH₃COO⁻, CF₃COO⁻, BF4⁻, PF₆⁻, (CN)₂N⁻, AlCl₄−, and Al₂Cl₇⁻, but the cations are not limited thereto. Other examples of the anions constituting the ionic liquid include PF₆⁻ and Cl⁻.

Examples of the ionic liquid include potassium bis(trifluoromethanesulfonyl)imide, potassium bis(nonafluorobutanesulfonyl)imide, 1-ethyl-3-methylimidazolium bis(trifluoromethanesulfonyl)imide, 1-methyl-1-propylpyrrolidinium bis(trifluoromethanesulfonyl)imide, and 1-butyl-3-methylimidazolium bis(trifluoromethanesulfonyl)imide.

Next, an example of a method of supplying the liquid heat transfer material as the first heat transfer material 104 and the second heat transfer material 105 will be described. FIG. 25 is a cross-sectional view illustrating an example of a configuration of the substrate support 12 when a liquid heat transfer material is supplied inside the wafer processing module 10. In FIG. 25, for the sake of simplicity of illustration, the flow path 13a formed in the base 13, the pin 110 and the hole 111 in the tray T, and the pin receiving hole 112 in the electrostatic chuck 14 are omitted.

When the liquid heat transfer material is supplied inside the wafer processing module 10, for example, the through-holes 13h and 14h formed in the substrate support 12 can be used. That is, as illustrated in FIG. 25, for example, by connecting a liquid supply 210 to the through-holes 13h and 14h formed in the base 13 and the electrostatic chuck 14 of the substrate support 12, the liquid heat transfer material (the second heat transfer material 105) can be supplied to a lower surface side of the tray T through the through-holes 13h and 14h. In this case, by forming through-holes 101h for supplying a liquid to the disk portion 101 of the tray T, the liquid heat transfer material (the first heat transfer material 104) can be supplied to the inside of the tray T. Since the through-hole 101h does not hinder the transfer of the tray Tw by the lift pin 15a, it is preferable to form the through-hole 101h offset from the through-hole 14h in a circumferential direction and/or a radial direction. The number of the through-holes 101h is not limited thereto, and the through-hole 101h may be disposed at a plurality of locations (preferably, three or more locations) in a surface of the disk portion 101. A shape of the through-hole 101h is not particularly limited, and the through-hole 101h may have any shape such as a circular shape or a rectangular shape in a plan view.

The liquid supply 210 includes a liquid source 211, a flow rate controller 212, a pressurization mechanism 213, and a decompression mechanism 214. Further, the liquid supply 210 has a liquid supply path 210a and a liquid discharge path 210b, the flow rate controller 212 and the pressurization mechanism 213 described above are disposed in the liquid supply path 210a, and the decompression mechanism 214 described above is disposed in the liquid discharge path 210b. Valves V1 to V5 for controlling a flow of the liquid heat transfer material are disposed in the liquid supply path 210a and the liquid discharge path 210b.

The liquid source 211 stores a liquid heat transfer material (the first heat transfer material 104 and/or the second heat transfer material 105) to be supplied toward the tray T. The flow rate controller 212 controls a flow rate of the liquid heat transfer material to be supplied toward the tray T. The pressurization mechanism 213 supplies an inert gas (for example, a N₂ gas) toward the liquid source 211, thereby delivering the liquid heat transfer material stored in the liquid source 211 toward the tray T. The decompression mechanism 214 decompresses the inside of the liquid source 211, thereby retrieving the liquid heat transfer material supplied toward the tray T into the liquid source 211. The valves V1, V2, and V3 are disposed in the liquid supply path 210a. Specifically, the valves V1 and V2 are disposed upstream and downstream of the flow rate controller 212, respectively, and the valve V3 is disposed in the vicinity of the pressurization mechanism 213. The valves V4 and V5 are disposed in the liquid discharge path 210b. Specifically, the valve V4 is disposed in the vicinity of the liquid source 211 in the liquid discharge path 210b, and the valve V5 is disposed in the vicinity of the decompression mechanism 214.

Further, when a liquid heat transfer material is used as the first heat transfer material 104 and the second heat transfer material 105, a sealing member for preventing leakage of the liquid heat transfer material is disposed in the substrate support 12. Specifically, as illustrated in FIG. 25, at least a first sealing member 215 for preventing leakage from an interface between the tray T and the electrostatic chuck 14 to an outer peripheral side of the substrate support 12, and a second sealing member 216 for preventing leakage to a lower side of the substrate support 12 through the through-hole 13h are disposed. For example, an O-ring made of FKM or FFKM can be used as a sealing member.

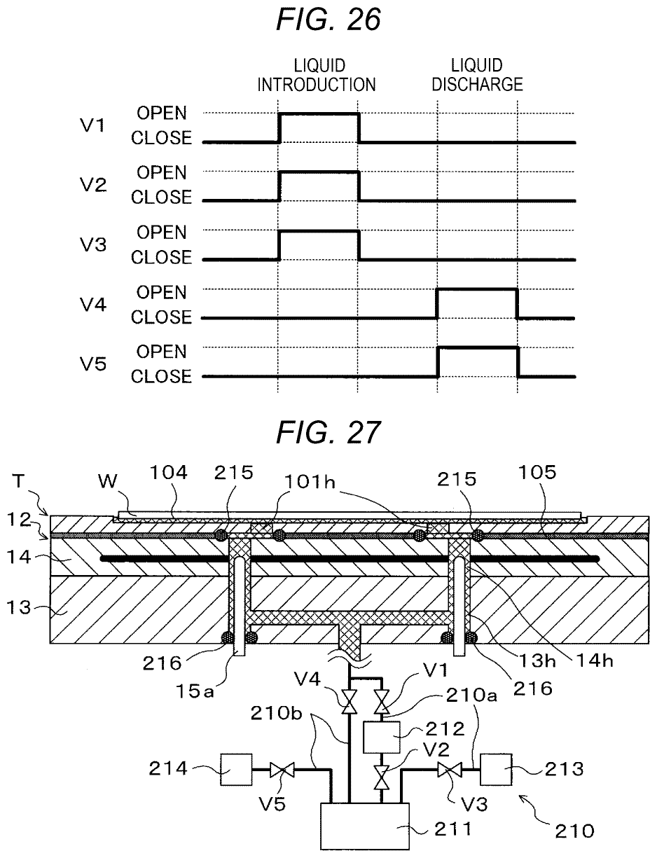

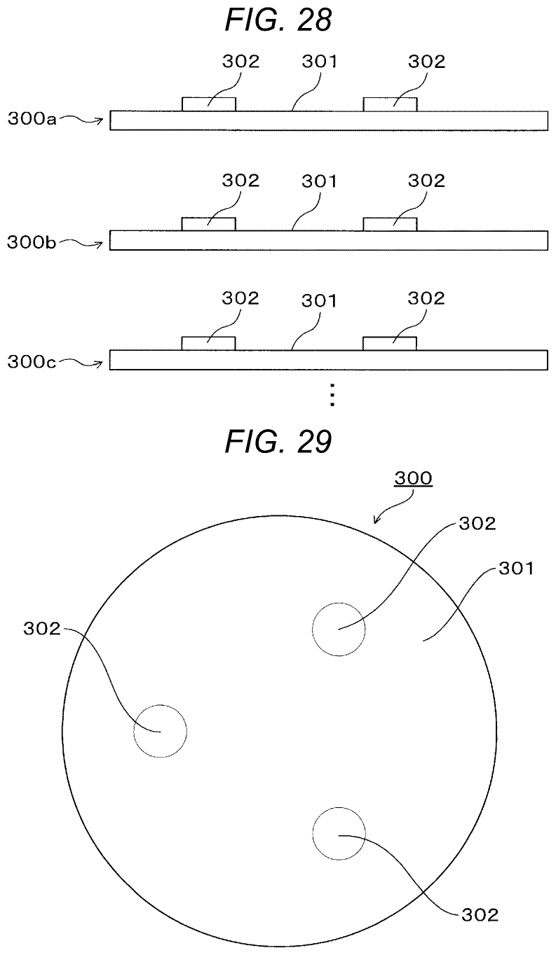

FIG. 26 is a sequence diagram illustrating operations of the valves V1 to V5 when the liquid supply 210 configured as described above supplies or discharges the liquid heat transfer material.

As illustrated in FIG. 26, when the liquid heat transfer material is supplied toward the tray T during wafer processing, the valves V1 to V3 in the liquid supply path 210a are opened, and the valves V4 and V5 in the liquid discharge path 210b are closed. Then, the liquid heat transfer material in the liquid source 211 is supplied to the flow rate controller 212 along with the pressurization of the liquid source 211 by the pressurization mechanism 213. The liquid heat transfer material whose flow rate is controlled by the flow rate controller 212 is then supplied as the second heat transfer material 105 to a lower surface side of the tray T through the through-holes 13h and 14h, and is supplied as the first heat transfer material 104 into the tray T through the through-holes 101h.

On the other hand, when the liquid heat transfer material supplied to the tray T is retrieved at the time of unloading the tray, the valves V4 and V5 in the liquid discharge path 210b are opened, and the valves V1 to V3 in the liquid supply path 210a are closed. Then, along with the decompression of the liquid source 211 by the decompression mechanism 214, the first heat transfer material 104 is retrieved into the liquid source 211 through the through-holes 101h, a lower surface side of the tray T, and the through-holes 13h and 14h, and the second heat transfer material 105 is retrieved into the liquid source 211 through the through-holes 13h and 14h.

The supply of the liquid heat transfer material as the first heat transfer material 104 and/or second heat transfer material 105 to the tray T is performed as described above. In this manner, by supplying the liquid heat transfer material using the existing through-holes 13h and 14h for the lift pin 15a for lifting and lowering the tray T, it is not necessary to form a new through-hole for supplying the liquid heat transfer material in the substrate support 12, and thus the liquid heat transfer material can be efficiently supplied and discharged.

FIG. 25 illustrates a case where a liquid heat transfer material is supplied from the liquid source 211 to both the inside of the tray T (the first heat transfer material 104) and a lower portion of the tray T (the second heat transfer material 105) by way of example. However, a liquid heat transfer material supplied from the liquid source 211 may be supplied to one of the inside of the tray T and the lower portion of the tray T.

For example, when a liquid heat transfer material is supplied from the liquid source 211 to only the inside of the tray T (the first heat transfer material 104) (for example, when the second heat transfer material 105 is a heat transfer sheet to be described later), at least the first sealing member 215 is disposed in a manner of surrounding peripheries of the through-hole 14h and the through-hole 101h as illustrated in FIG. 27. In this case, in order to supply a liquid heat transfer material only to the inside of the tray T, a heat transfer sheet is not disposed at a part between the tray T and the tray placing surface of the electrostatic chuck 14.

For example, when a liquid heat transfer material is supplied from the liquid source 211 to only a lower surface side of the tray T (the second heat transfer material 105) (for example, when the first heat transfer material 104 is a heat transfer sheet to be described later), the arrangement of the first sealing member 215 does not change from that in FIG. 25, and the through-hole 101h may not be formed in the disk portion 101 of the tray T.

In this manner, even when a liquid heat transfer material is supplied from the liquid source 211 to only one of the inside of the tray T (the first heat transfer material 104) or the lower portion of the tray T (the second heat transfer material 105), the liquid heat transfer material can be efficiently supplied and discharged by performing the supply of the liquid heat transfer material using the through-holes 13h and 14h for lifting and lowering the tray T.

In the examples illustrated in FIGS. 25 and 27, the first heat transfer material 104 and/or the second heat transfer material 105 serving as a liquid heat transfer material are supplied inside the wafer processing module 10. However, at least the first heat transfer material 104 inside the tray T may be supplied in advance outside the wafer processing module 10.

In one embodiment, before the wafer W is placed on the tray T, a liquid heat transfer material (the first heat transfer material 104) is supplied toward the recess 103 of the tray T in a coating apparatus. A method of supplying the liquid heat transfer material to the tray T is not particularly limited, and for example, the liquid heat transfer material may be supplied by so-called spin coating in which the liquid heat transfer material is supplied from a nozzle disposed above the tray T while the tray T is rotated.

When the liquid heat transfer material is supplied, the liquid heat transfer material may be supplied to a position inward of a radial position where the hole 111 is formed in the tray T, so that the liquid heat transfer material does not leak from the hole 111 exposed to the recess 103 in the third state illustrated in FIG. 24. The liquid heat transfer material supplied to this position is pushed and spread between the back surface of the wafer W and the recess 103 when the wafer W is accommodated in the recess 103 of the tray T. When the pushed and spread liquid heat transfer material reaches the hole 111, an outer surface of the pin 110 comes into contact with the inner surface of the hole 111 without a gap, so that the tray T can be in a state where the liquid heat transfer material does not leak from the hole 111. Thereafter, the wafer W is placed on the tray T supplied with the liquid heat transfer material, or the tray T supplied with the liquid heat transfer material is stored in the tray stocker 6.

In one embodiment, after the tray T is subjected to all processing and separated from the wafer W, the recess 103 is cleaned in a cleaning apparatus, and the first heat transfer material 104 is removed. A method of cleaning the tray is not particularly limited, and for example, so-called spin cleaning may be performed in which a cleaning liquid is supplied from a nozzle disposed above the tray T while the tray T is rotated.

The coating apparatus for supplying a liquid heat transfer material to the tray T and the cleaning apparatus for cleaning the tray T may be provided inside or outside the wafer processing system 1. Accordingly, the supply of a liquid heat transfer material (the first heat transfer material 104) to the tray T may be performed inside or outside the wafer processing system 1.

As described above, by using a liquid heat transfer material as the first heat transfer material 104, the wafer W and the tray T can be brought into appropriate and full thermal contact with each other via the liquid heat transfer material. Therefore, heat transfer efficiency between the wafer W and the tray T can be improved. Further, by using a liquid heat transfer material as the second heat transfer material 105, the tray T and the electrostatic chuck 14 can be brought into appropriate and full thermal contact via the liquid heat transfer material. Therefore, heat transfer efficiency between the tray T and the electrostatic chuck 14 can be improved, and thus heat transfer efficiency between the wafer W and the electrostatic chuck 14 can be improved. As a result, the entire surface of the wafer W can be properly cooled by a heat transfer fluid flowing through the inside of the base 13.

In addition to the effects described above, according to the tray T in the present embodiment, the wafer W accommodated in the recess 103 of the tray T can be easily loaded and unloaded by the pin 110 and the hole 111.

In the example illustrated in FIG. 27, the through-holes 13h and 14h for the lift pin 15a formed in advance in the substrate support 12 are used as a flow path for supplying a liquid heat transfer material. However, of course, a new through-hole for supplying a liquid heat transfer material may be formed in the substrate support 12. <Heat Transfer Sheet>

Next, details of a heat transfer sheet used as the first heat transfer material 104 and/or the second heat transfer material 105 will be described.

When a heat transfer sheet is used as the first heat transfer material 104 and/or the second heat transfer material 105, a material that does not deteriorate under at least vacuum (reduced pressure) and has high heat conductivity and plasma resistance is selected as the heat transfer sheet. A thickness of the heat transfer sheet may be, for example, less than 100 μm. Examples of the heat transfer sheet include a Si-containing material, a SiC-containing material, a W-containing material, an Al₂O₃-containing material, an AlN-containing material, a nano-SiC-containing material, a diamond powder-containing material, a CNT-containing material, a fluororubber-based sheet, a silicone sheet, an acrylic sheet, or a mesh sheet impregnated with the liquid heat transfer material described above. Further, when the fluororubber-based sheet, the silicone sheet, or the acrylic sheet described above is used as the heat transfer sheet as the first heat transfer material 104, the heat transfer sheet preferably has an ultra violet (UV) curing property. Further, a heat transfer sheet selected as the first heat transfer material 104 preferably has thermoplasticity.

In one embodiment, the first heat transfer material 104, which is a heat transfer sheet having an UV curing property and/or thermoplasticity, for example, is cured by performing UV irradiation when the wafer W is accommodated in the recess 103 of the tray T in a substrate processing method to be described later. As a result, the tray T and the wafer W are bonded to each other, so that a high contact state can be maintained. Further, when the wafer W is separated from the tray T, the first heat transfer material 104 may be softened by performing heating, and the separation can be facilitated.

### <Other Heat Transfer Materials>

In the above description, a case where a liquid heat transfer material or a heat transfer sheet is used as the first heat transfer material 104 and the second heat transfer material 105 has been described by way of example. However, when the first heat transfer material 104 and the second heat transfer material 105 are attached externally and newly provided to the tray T in this manner, an interface between the wafer W and the base 13 may increase and a combined thermal resistance for cooling the wafer W by a heat transfer fluid flowing through the flow path 13a may increase, as compared with a case where the wafer W is attracted and held on the electrostatic chuck 14 as in the related art.

Therefore, in the tray T according to the present embodiment, instead of or in addition to externally attaching the first heat transfer material 104 and the second heat transfer material 105 as described above, a carbon nanotube (CNT) serving as a heat transfer layer may be combined on a surface of the tray T (the recess 103 and a lower surface side of the tray T).

According to the present embodiment, it is not necessary to apply an electrostatic attraction voltage to the substrate support 12 in order to reduce a combined thermal resistance in the related art, and efficient high heat transfer can be achieved simply by bringing the CNT into contact with the electrostatic chuck 14. Accordingly, an interface thermal resistance generated in a tray structure according to the present embodiment can be reduced, reduction of the number of electrostatic electrodes for applying the electrostatic attraction voltage can be achieved, power down can be achieved, and a structure around a lower electrode can be simplified.

The CNT combined in the tray T as described above is particularly easy to react with oxygen(O)-based plasma, and may be consumed during plasma processing in the wafer processing module 10, which may cause generation of particles. Therefore, when the CNT is combined on the surface of the tray T in this manner, a sealing member for protecting the CNT from plasma may be disposed. FKM or FFKM can be used as a material of the sealing member.

A heat transfer layer combined on the surface of the tray T (the recess 103 and the lower surface side of the tray T) is not limited to the CNT, and may be appropriately selected as long as the heat transfer layer is made of a material which is combined on the tray T and can improve heat transfer performance, such as nano-SiC, a diamond film, or a sol-gel film.

### <Tray Stocker>

Next, details of a configuration of the tray stocker 6 serving as a storage module for storing the tray T according to the present embodiment will be described.

FIG. 28 is a side view schematically illustrating a partial configuration of the inside of the tray stocker 6. As illustrated in FIG. 28, a plurality of racks 300a, 300b, and 300c are provided inside the tray stocker 6. In the following description, when a common configuration of the plurality of racks 300a, 300b, and 300c is described, these racks will not be distinguished from one another, and will be simply referred to as [racks 300]. The racks 300 are spaced apart from each other in the up-down direction to allow the transfer arm 7a of the first transfer mechanism 7 to enter to lift and unload the tray T in a wafer processing method to be described later. Although only three racks 300 are illustrated in FIG. 28, the present disclosure is not limited thereto, and more racks 300 may be provided.

FIG. 29 is a plan view illustrating one rack 300 as viewed from above. As illustrated in FIGS. 28 and 29, the rack 300 includes a rack base 301 and a plurality of rack scaffoldings 302 on an upper surface of the rack base 301. The rack scaffolding 302 is provided at least at a position corresponding to the pin 110 in the tray T in a state where the tray T is placed on the rack 300. In the present embodiment, since the three pins 110 are provided at rotationally symmetrical positions in the tray T, the three rack scaffoldings 302 are also provided at rotationally symmetrical positions. In the example illustrated in FIG. 29, the rack base 301 is circular, but may have any other shape.

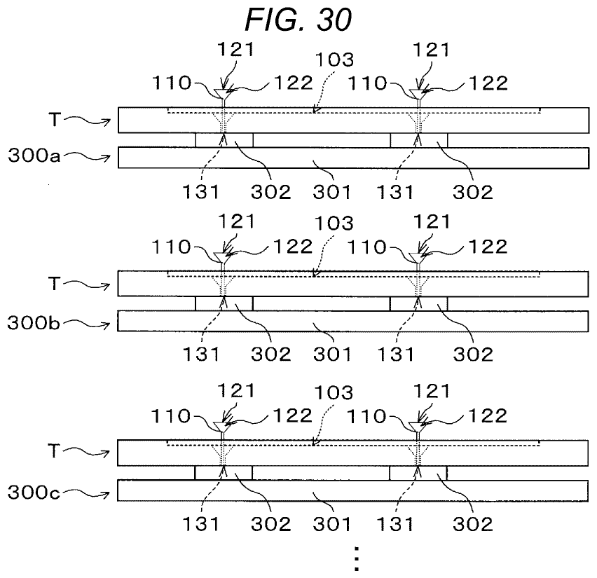

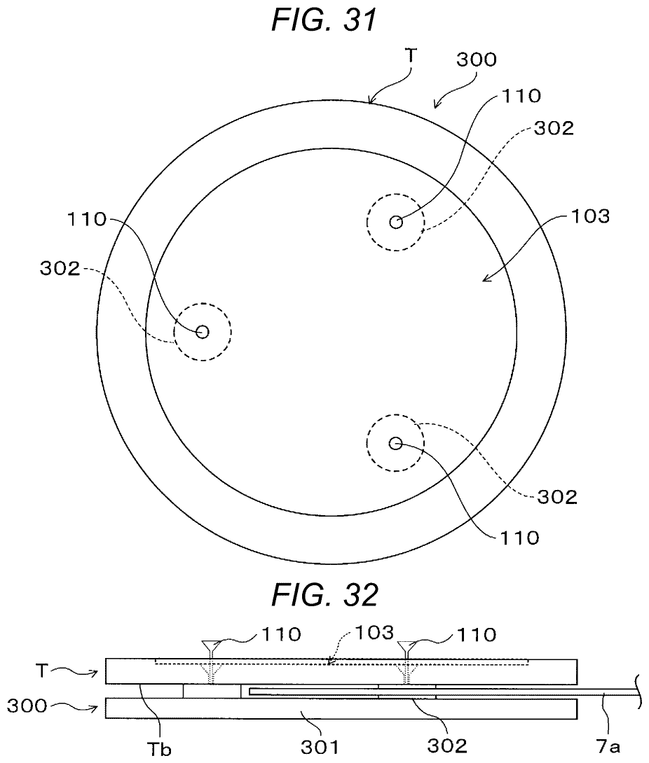

FIGS. 30 and 31 are a side view and a plan view illustrating an example of a state where the tray T is placed and stored on the rack 300 in the tray stocker 6. As illustrated in FIG. 30, the tray T placed on the rack 300 is in the third state where the lower end 131 of the base 132 of the pin 110 comes into contact with the rack scaffolding 302 and does not protrude from the lower surface Tb of the tray T, and the upper end 121 of the head 122 of the pin protrudes from the recess 103. That is, the tray T is stored in the third state on the rack 300 in the present embodiment. The rack 300 functions as a substrate loading and unloading portion in the present embodiment.

In one embodiment, trays T having different dimensions are placed on the respective racks 300a, 300b, and 300c. As an example, inner diameters of the recesses 103 of the trays T placed on the respective racks 300a, 300b, and 300c are different from one another. In another embodiment, the trays T having the same dimensions are placed on the respective racks 300a, 300b, and 300c. In still another embodiment, a plurality of tray stockers 6 are provided. In this case, trays T having different dimensions are accommodated in the plurality of tray stockers 6, and trays T having the same dimensions are placed on the plurality of racks 300a, 300b, and 300c in one tray stocker 6.

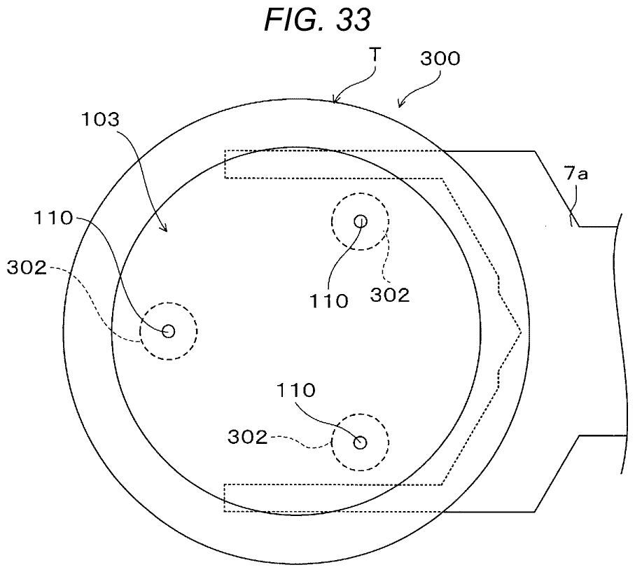

FIGS. 32 and 33 are a side view and a plan view illustrating an example of a positional relationship with the transfer arm 7a when the tray T is placed on the rack 300 in the tray stocker 6 or the tray T is lifted from the rack 300. As illustrated in FIG. 30, the rack base 301 of the rack 300 and the lower surface Tb of the tray T are spaced apart from each other by the rack scaffolding 302, so that the transfer arm 7a can enter therebetween. As illustrated in FIG. 33, the rack scaffolding 302 is provided at a position and with a diameter at which the rack scaffolding 302 does not interfere with the transfer arm 7a in a plan view.

### <First Wafer Processing Method>

Next, a first wafer processing method Mt1, which is an example of a wafer processing method including transfer of the wafer W, the tray T, and the tray Tw in the first state, loading and unloading of the tray T and the wafer W, and processing of the wafer W in the wafer processing system 1 described above, will be described.

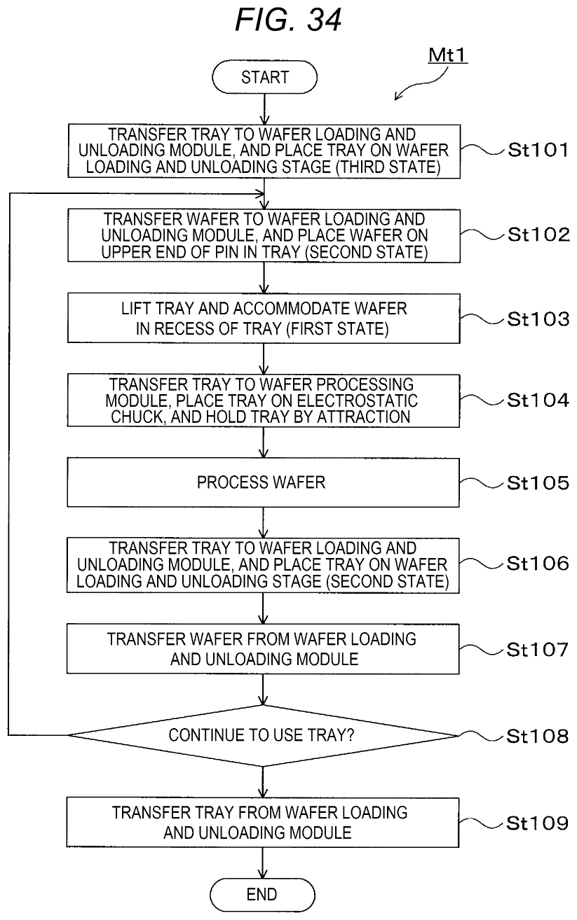

FIG. 34 is a flowchart illustrating an outline of the first wafer processing method Mt1 according to the present embodiment. In the following description, types of the first heat transfer material 104 and the second heat transfer material 105 are not particularly limited. In the present embodiment, the first heat transfer material 104 and the second heat transfer material 105 are already formed in the tray T before the wafer processing method. In one embodiment, the first heat transfer material 104 and the second heat transfer material 105 are formed in the tray T during the first wafer processing method Mt1.

The first wafer processing method Mt1 according to the present embodiment includes the following steps St101 to St109.

In step St101, the tray T is transferred from the tray stocker 6 to the wafer loading and unloading module 8 and placed on the wafer loading and unloading stage 200. As described above, in a state where the tray T is placed on the wafer loading and unloading stage 200 serving as a substrate loading and unloading portion in the present embodiment, the tray T is in the third state (FIG. 24) where the upper end 121 of the pin 110 protrudes from the recess 103.

In step St102, the wafer W is transferred from the hoop F to the wafer loading and unloading stage 200 in the wafer loading and unloading module 8. Subsequently, the wafer W is placed on the upper end 121 of the pin 110 in the tray T in the third state placed on the wafer loading and unloading stage 200, and the tray T is set to the second state where the upper end 121 of the pin 110 and the wafer W come into contact with each other (FIG. 6).

In step St103, the tray T is set to the first state where the tray T in the second state is lifted from the wafer loading and unloading stage 200 (FIG. 5). That is, by lifting the tray T, the base 132 of the pin 110 is moved downward relative to the base receiving portion 142 during the lower end 131 of the pin 110 is separated from the stage scaffolding 200b of the wafer loading and unloading stage 200, and the wafer W is relatively lowered downward. Thereafter, the back surface Wb of the wafer W comes into contact with the recess 103 of the tray T, so that the wafer W is accommodated in the recess 103. At this time, the pin 110 is locked and held by bringing the head 122 into contact with the head receiving portion 141.

In step St104, the tray Tw in the first state is transferred from the wafer loading and unloading module 8 to the wafer processing module 10. The tray Tw is placed on the electrostatic chuck 14 and attracted and held so that the lower end 131 of the pin 110 is inserted into the pin receiving hole 112.

In step St105, the wafer is processed in the wafer processing module 10. The processing performed on the wafer W in the wafer processing module 10 is, for example, plasma processing such as etching. Specifically, for example, after the wafer W is loaded, the inside of the plasma processing chamber 11 is decompressed to a desired vacuum level, and then a desired processing gas is supplied into the plasma processing space 11s in the plasma processing. Thereafter, at least one RF signal (RF power) is supplied to at least one lower electrode and/or at least one upper electrode by the RF power source 31, and the processing gas is excited to generate plasma. Then, the wafer W is subjected to plasma processing by the action of the plasma generated in this manner. At this time, the plasma processing of the wafer W is performed in a state where the wafer W is placed on the tray T. At this time, the wafer W and the tray T are in full contact with each other via the first heat transfer material 104, and the tray T and the electrostatic chuck 14 are in full contact with each other via the second heat transfer material 105. As a result, the entire surface of the wafer W is appropriately thermally connected to the electrostatic chuck 14, and the wafer W is efficiently cooled by the heat transfer fluid flowing through the inside of the base 13.

In step St106, after the processing on the wafer W is completed, the tray Tw in the first state is transferred from the wafer processing module 10 to the wafer loading and unloading module 8, and placed on the wafer loading and unloading stage 200. The tray Tw placed on the wafer loading and unloading stage 200 is set to the second state where the wafer W is separated from the recess of the tray T. Specific actions are as follows. On the wafer loading and unloading stage 200, the lower end 131 of the pin 110 in the tray Tw is in contact with the stage scaffolding 200b of the wafer loading and unloading stage 200. Subsequently, in this state, the lower surface Tb of the tray T is lowered until the lower surface Tb comes into contact with the stage scaffolding 200b of the wafer loading and unloading stage 200, so that the base 132 of the pin 110 is moved upward relative to the base receiving portion 142 and the wafer W is pushed upward. Accordingly, in a state where the lower surface Tb of the tray T is in contact with the stage scaffolding 200b of the wafer loading and unloading stage 200, the wafer W is separated from the recess 103 of the tray T in a state where the wafer W is placed on the upper end 121 of the pin 110. In one embodiment, when the wafer loading and unloading stage 200 is configured as an electrostatic chuck, when a magnetic force is applied to the wafer loading and unloading stage 200 and the annular portion 102 of the tray T, or when the annular portion 102 of the tray T can be pushed downward by the transfer arm 7a, or the like, the tray T can be more strongly pressed against the wafer loading and unloading stage 200. In this case, when the tray T is more strongly pressed against the wafer loading and unloading stage 200, the lower end 131 of the pin 110 is more strongly pressed against the stage scaffolding 200b of the wafer loading and unloading stage 200, and as a reaction, the base 132 of the pin 110 can be moved upward and the wafer W can be pushed upward more strongly. Accordingly, even when the wafer W and the tray T are bonded to each other, the wafer W can be easily separated from the tray T.

In step St107, the wafer W is lifted from the tray T in the second state, the wafer W is unloaded from the wafer loading and unloading module 8, and transferred into, for example, the hoop F. As a result of transferring the wafer W in step St107, the tray T in the third state is left on the wafer loading and unloading stage 200 of the wafer loading and unloading module 8.

In step St108, it is determined whether to continue to use the tray T in the third state left on the wafer loading and unloading stage 200 of the wafer loading and unloading module 8. When the tray T is continued to be used, the processing returns to step St102, and the tray T in the third state is used in step St102. When the tray T is not continued to be used, in step St109, the tray T is unloaded from the wafer loading and unloading module 8, and for example, is transferred to and stored in the tray stocker 6.

According to the series of steps St101 to St109, in a configuration in which the wafer W is accommodated in the recess 103 of the tray T and the temperature uniformity in a surface of the wafer W during the processing is improved, the wafer W and the tray T can be easily loaded and unloaded.

### <Second Wafer Processing Method>

Next, a second wafer processing method Mt2, which is an example of a wafer processing method including transfer of the wafer W, the tray T, and the tray Tw in the first state, loading and unloading of the tray T and the wafer W, and processing of the wafer W in the wafer processing system 1 described above, will be described.

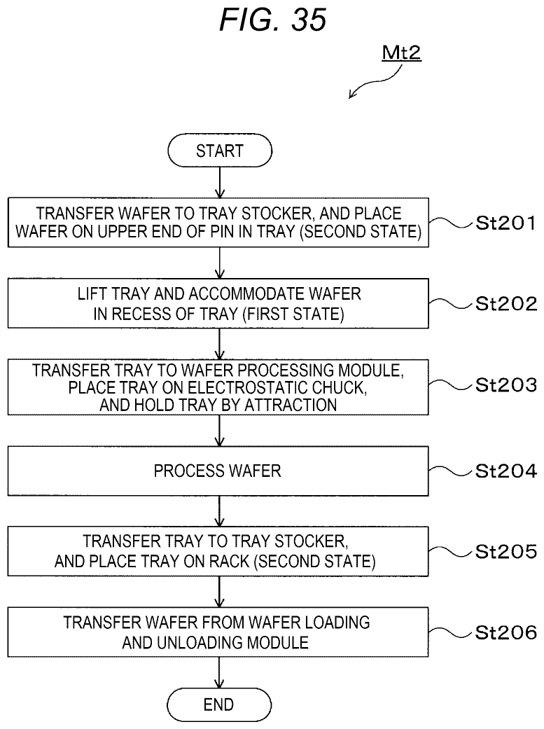

FIG. 35 is a flowchart illustrating an outline of the second wafer processing method Mt2 according to the present embodiment. The second wafer processing method Mt2 according to the present embodiment includes the following steps St201 to St206.

In step St201, the wafer W is transferred from the hoop F to the rack 300 in the tray stocker 6. As described above, on the rack 300 serving as a substrate loading and unloading portion in the present embodiment, the tray T is in the third state (FIG. 30) where the upper end 121 of the pin 110 protrudes from the recess 103. The wafer W is placed on the upper end 121 of the pin 110 in the third state, and the tray T is set to the second state where the upper end 121 of the pin 110 and the wafer W come into contact with each other (FIG. 6).

In step St202, the tray T in the second state is lifted from the rack 300 and set to the first state (FIG. 5). That is, by lifting the tray T, the base 132 of the pin 110 is moved downward relative to the base receiving portion 142 during the lower end 131 of the pin 110 is separated from the rack scaffolding 302, and the wafer W is relatively lowered downward. Thereafter, the back surface Wb of the wafer W comes into contact with the recess 103 of the tray T, so that the wafer W is accommodated in the recess 103. At this time, the pin 110 is locked and held by bringing the head 122 into contact with the head receiving portion 141.

In step St203, the tray Tw in the first state is transferred from the tray stocker 6 to the wafer processing module 10. The tray Tw is placed on the electrostatic chuck 14 and attracted and held so that the lower end 131 of the pin 110 is inserted into the pin receiving hole 112.

In step St204, the wafer is processed in the wafer processing module 10. The processing performed on the wafer W in the wafer processing module 10 is the same as the step St105 in the first wafer processing method Mt1.

In step St205, after the processing on the wafer W is completed, the tray Tw in the first state is transferred from the wafer processing module 10 to the tray stocker 6 and placed on the rack 300. The tray Tw placed on the rack 300 is set to the second state after the wafer W is separated from the recess of the tray T. Specific actions are as follows. In the tray stocker 6, the lower end 131 of the pin 110 is in contact with the rack scaffolding 302 in the tray Tw. Subsequently, in this state, the lower surface Tb of the tray T is lowered until the lower surface Tb comes into contact with the rack scaffolding 302, so that the base 132 of the pin 110 is moved upward relative to the base receiving portion 142 and the wafer W is pushed upward. Accordingly, in a state where the lower surface Tb of the tray T is in contact with the rack scaffolding 302, the wafer W is separated from the recess 103 of the tray T in a state where the wafer W is placed on the upper end 121 of the pin 110.

In step St206, the wafer W is lifted from the tray T in the second state, the wafer W is unloaded from the tray stocker 6, and transferred to, for example, the hoop F. As a result of transferring the wafer W in step St206, the tray T in the third state is left on the rack 300 of the tray stocker 6. The left tray T is directly stored on the rack 300.

According to the series of steps St201 to St206, in a configuration in which the wafer W is accommodated in the recess 103 of the tray T and the temperature uniformity in a surface of the wafer W during the processing is improved, the wafer W and the tray T can be easily loaded and unloaded. As compared with the first wafer processing method Mt1, the step of transferring the tray T can be omitted, and the throughput can be further improved.

In one embodiment, step 201 of the second wafer processing method Mt2 may further include a step of selecting the tray T on which the wafer W transferred into the tray stocker 6 is to be placed. As described above, in one embodiment, the trays T having different inner diameters of the recesses 103 are placed on the respective racks 300a, 300b, and 300c. An outer diameter of the wafer W is measured in, for example, an orienter module connected to the atmospheric transfer module 2. In this step, a rack on which the tray T is placed is appropriately selected from the plurality of racks 300a, 300b, and 300c so as to reduce a difference between the outer diameter of the wafer W and an inner diameter of the tray T. Thereafter, it is possible to reduce the gap G between the wafer W and the recess 103 of the tray T to be smaller by placing the wafer W on the tray T placed on the selected rack 300.

In another embodiment, step 201 of the second wafer processing method Mt2 may further include a step of selecting one tray stocker 6 to be accessed from the plurality of tray stockers 6. As described above, in one embodiment, a plurality of the tray stockers 6 are provided, and trays T having different dimensions are stored in these tray stockers 6. In this step, a tray stocker in which the tray T is stored is appropriately selected from the plurality of tray stockers 6 so as to reduce a difference between the outer diameter of the wafer W whose outer diameter was measured in the same manner as described above and the inner diameter of the tray T. Thereafter, it is possible to reduce the gap G between the wafer W and the recess 103 of the tray T to be smaller by placing the wafer W on the tray T placed on the rack 300 in the selected tray stocker 6.

In one embodiment, in the wafer processing system 1 that performs the first wafer processing method Mt1, the rack 300 provided in the tray stocker 6 may be configured not to function as a substrate loading and unloading portion. Further, in the wafer processing system 1 that performs the second wafer processing method Mt2, the wafer loading and unloading module 8 may not be provided.

### <Method of Transferring and Placing Tray on Electrostatic Chuck>

Next, a method of transferring and placing the tray Tw on the electrostatic chuck 14 in the wafer processing module 10 in step St104 of the first wafer processing method Mt1 or step St203 of the second wafer processing method Mt2 according to the present embodiment will be described. In the following drawings, the pin 110 and the hole 111 in the tray T are omitted.

### (1) Use of Lift Pin

When the tray Tw is placed on the tray support surface of the electrostatic chuck 14, the lift pins 15a inserted into the through-holes 13h and 14h described above can be used. That is, for example, in a state where the tray Tw is disposed above the electrostatic chuck 14 by the second transfer mechanism 18, the lift pins 15a protrude from an upper surface of the electrostatic chuck 14 through the through-holes 13h and 14h, so that the tray Tw is transferred from the second transfer mechanism 18 to upper end portions of the lift pins 15a. Then, after the second transfer mechanism 18 is retracted, the lift pins 15a are lowered to transfer the tray Tw from the lift pins 15a onto the tray support surface of the electrostatic chuck 14.

In this manner, the transfer is performed in a manner that a lower surface of the tray Tw is supported by the second transfer mechanism 18 and the lift pins 15a, so that the tray Tw can be transferred to the electrostatic chuck 14 without damaging a device layer formed on a surface of the wafer W placed on the tray T.

### (2) Holding Tray From Upper or Side Surface

When the wafer W is transferred to the electrostatic chuck 14, it is necessary to prevent the damage to the device layer formed on a front surface of the wafer W in this manner, and in wafer processing in the related art without using the tray T, in principle, it is necessary to hold a back surface side of the wafer W and perform the transfer.

In this respect, in the wafer processing according to the present embodiment, the wafer W is transferred in a state where the wafer W is placed on the tray T as described above. Further, in the present embodiment, the tray T has the annular-shaped annular portion 102 disposed outside the wafer W in the radial direction.

Therefore, in the wafer processing according to the present embodiment, instead of supporting the lower surface of the tray Tw by the second transfer mechanism 18 and the lift pin 15a as described above, the tray T may be held from an upper side or a side surface side and transferred between the second transfer mechanism 18 and the electrostatic chuck 14.

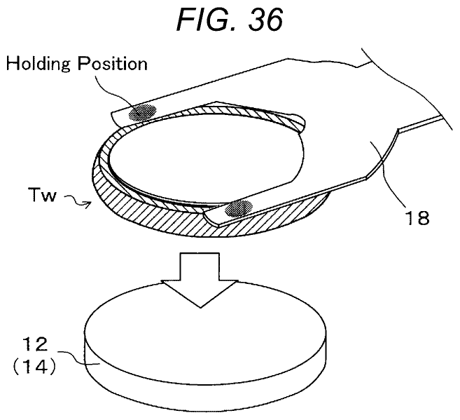

Specifically, for example, as illustrated in FIG. 36, the annular portion 102 of the tray T on which the wafer W is placed may be held from an upper side and transferred by the second transfer mechanism 18. At this time, since the damage to the device layer formed on the surface of the wafer W is prevented by holding the annular portion 102 of the tray T, the second transfer mechanism 18 may physically hold the annular portion 102 of the tray T and transfer the tray T. A method of holding the tray T by the second transfer mechanism 18 is not particularly limited, and any method such as a magnet, vacuum attraction, or electrostatic attraction can be selected.

In this manner, in the wafer processing according to the present embodiment in which the wafer W to be processed is loaded on the tray T and transferred, since it is not necessary to bring the wafer W and the second transfer mechanism 18 into direct contact with each other by holding the tray T by the second transfer mechanism 18, holding and transfer can be performed by accessing, from above, the tray Tw on which the wafer W is loaded. Further, since the tray Tw can be held from above in this manner, it is not necessary to transfer the tray Tw to the electrostatic chuck 14 via the lift pin 15a as in the related art when the tray Tw is transferred to the electrostatic chuck 14, and the tray Tw can be directly transferred from the second transfer mechanism 18 to the electrostatic chuck 14. Therefore, when the tray Tw is held from an upper side or a side in this manner, the lifter 15 for transferring the tray Tw to the electrostatic chuck 14 can be omitted, and the configuration of the wafer processing module 10 can be simplified.

### <Method of Fixing Tray to Substrate Support>

Next, an example of a method of fixing the tray Tw transferred as described above to the substrate support 12 (the electrostatic chuck 14) in the wafer processing module 10 will be described.

As described above, the tray Tw is held on the tray support surface of the substrate support 12. However, in order to efficiently cool the wafer W by the heat transfer fluid flowing through the flow path 13a formed in the base 13, it is necessary to increase a pressing force (surface pressure) of the tray Tw against the electrostatic chuck 14. Therefore, in the following description, in order to improve the cooling efficiency of the wafer W, a method of holding the tray Tw on the electrostatic chuck 14 by a pressing force equal to or larger than the weight of the tray Tw will be described.

### (1) Electrostatic Attraction

As illustrated in FIG. 2, the electrostatic chuck 14 of the substrate support 12 includes the electrostatic electrode 14b for supporting the tray Tw on the tray support surface. The tray Tw can be attracted and held on the substrate support 12 by using the electrostatic electrode 14b.

First, a case where the disk portion 101 of the tray T is made of a conductive material will be described.

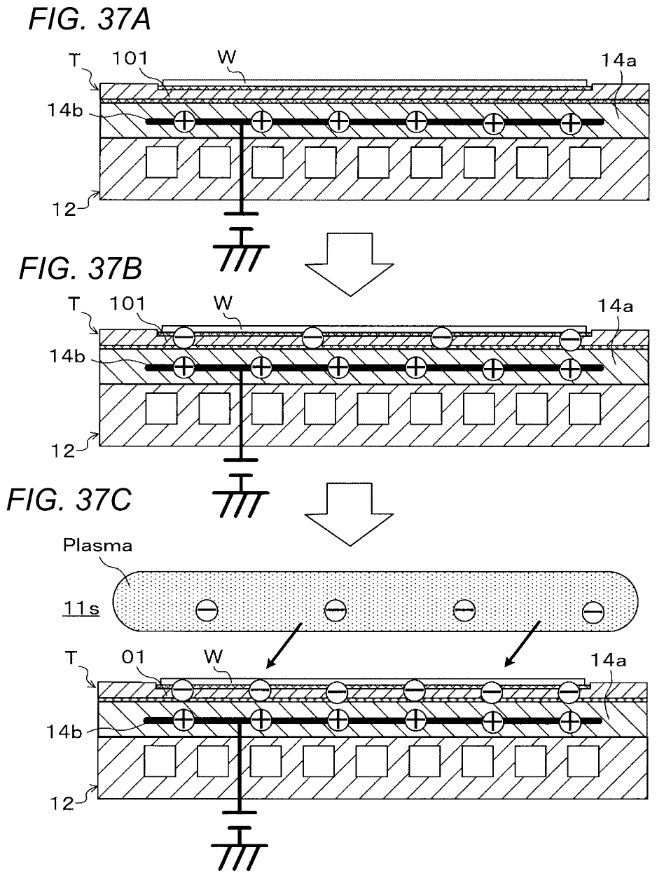

When the tray T is attracted and held, first, as illustrated in FIG. 37A, a voltage (positive (+) charges in the illustrated example) is applied to the electrostatic electrode 14b. Then, the electrostatic electrode 14b is positively (+) charged.

When the electrostatic electrode 14b is positively (+) charged, as illustrated in FIG. 37B, charges of an opposite polarity (that is, negative (−) charges) to the charges accumulated in the electrostatic electrode 14b are accumulated in the disk portion 101 of the tray T or the wafer W, while the positive charges and the negative charges are separated by the ceramic member 14a that is a dielectric. Then, a Coulomb force is generated with the tray T (the wafer W) and the electrostatic electrode 14b serving as both electrodes, and thus the tray Tw is attracted and held onto the tray support surface of the electrostatic chuck 14.

Further, in a case where the tray Tw is attracted and held onto the electrostatic chuck 14 by the Coulomb force in this manner, the Coulomb force can be increased to increase an attraction and holding force of the electrostatic chuck 14 by generating plasma in the wafer processing module 10. Specifically, as illustrated in FIG. 37C, charges of an opposite polarity (that is, negative (−) charges) to the charges accumulated in the electrostatic electrode 14b are moved from the plasma to the disk portion 101 of the tray T or the wafer W by generating plasma in the plasma processing space 11s. That is, the Coulomb force can be increased by compensating charges from the plasma, and the tray Tw can be more firmly attracted and held.

Next, a case where the disk portion 101 of the tray T is made of an insulating material will be described. When the disk portion 101 of the tray T is made of an insulating material, a charging electrode 101b is disposed in the disk portion 101.

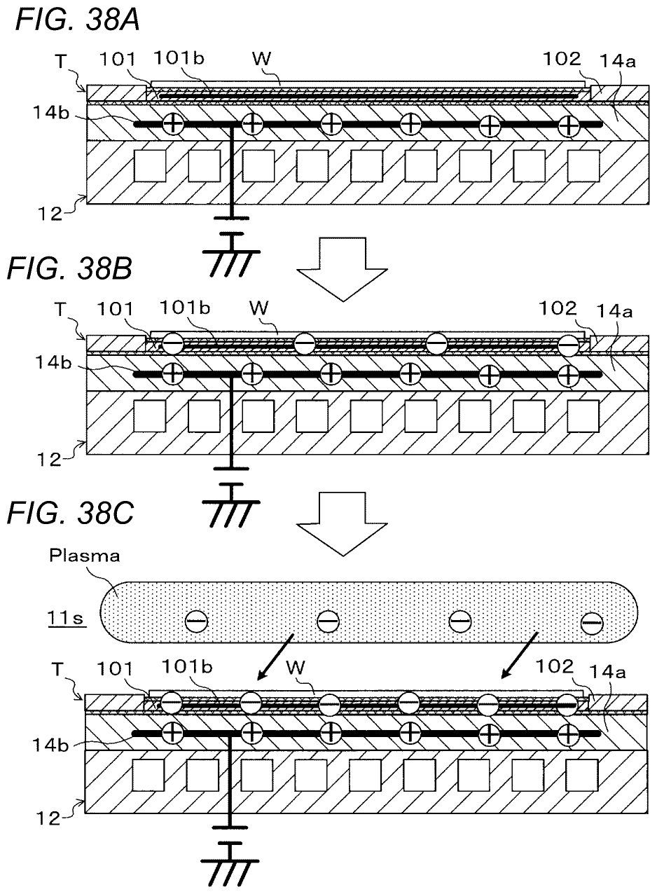

When the tray T is attracted and held, first, as illustrated in FIG. 38A, a voltage (positive (+) charges in the illustrated example) is applied to the electrostatic electrode 14b. Then, the electrostatic electrode 14b is positively (+) charged.

When the electrostatic electrode 14b is positively (+) charged, as illustrated in FIG. 38B, charges of an opposite polarity (that is, negative (−) charges) to the charges accumulated in the electrostatic electrode 14b are accumulated in the charging electrode 101b disposed in the disk portion 101 and the wafer W, while the positive charges and the negative charges are separated by the ceramic member 14a that is a dielectric and the disk portion 101 that is an insulating member. Then, a Coulomb force is generated with the charging electrode 101b (the wafer W) and the electrostatic electrode 14b serving as both electrodes, and thus the tray Tw is attracted and held onto the tray support surface of the electrostatic chuck 14.

When the disk portion 101 of the tray T is made of an insulating material, the Coulomb force can be increased to increase the attraction and holding force of the electrostatic chuck 14 by generating plasma in the wafer processing module 10. Specifically, as illustrated in FIG. 38C, charges of an opposite polarity (that is, negative (−) charges) to the charges accumulated in the electrostatic electrode 14b are moved from the plasma to the charging electrode 101b and the wafer W by generating plasma in the plasma processing space 11s. That is, the Coulomb force can be increased by compensating charges from the plasma, and the tray Tw can be more firmly attracted and held.

In this manner, regardless of whether the disk portion of the tray T is made of a conductive member or an insulating member, the tray Tw can be appropriately attracted and held on the tray support surface by applying a voltage to the electrostatic electrode 14b of the electrostatic chuck 14. In this case, the Coulomb force between the tray Tw and the electrostatic chuck 14 can be increased and the tray Tw can be more firmly attracted and held by generating plasma in the plasma processing space 11s.

By using the Coulomb force in this manner, the attraction and holding of the tray Tw can be controlled simply by controlling the voltage applied to the electrostatic electrode 14b. Therefore, the tray Tw can be attracted and held without complicating the structure of the substrate support 12. Further, since the attraction and holding can be performed by simple voltage control in this manner, controllability is improved, and the attraction force in a surface of the tray Tw can be uniformly controlled, that is, a surface pressure of the tray Tw against the electrostatic chuck 14 is uniformly controlled, so that the cooling efficiency of the wafer W can be improved, and the reproducibility of the attraction force can be improved.

When the tray Tw is attracted and held by the Coulomb force in this manner, by controlling the attraction force in a surface of the tray Tw, it is possible to control tilting at an outermost peripheral portion of the wafer W when the wafer processing in the wafer processing module 10 is an etching processing as plasma processing.

When the annular portion 102 of the tray T is consumed by the plasma processing and an upper surface height of the annular portion 102 changes, a plasma sheath position formed above an outer peripheral portion of the wafer W is lowered below a plasma sheath position formed above a central portion of the wafer W, so that an incidence angle of ions on the wafer W is tilted, and an etched groove formed at the outermost peripheral portion of the wafer W is tilted (tilting).

Therefore, in the wafer processing module 10 according to the present embodiment, the attraction force is controlled in a surface of the tray Tw (more specifically, two regions of a circular region on an inner side in the radial direction and an annular region on an outer side in the radial direction) by the electrostatic chuck 14, according to a consumption level (consumed amount) of the annular portion 102 of the tray T.

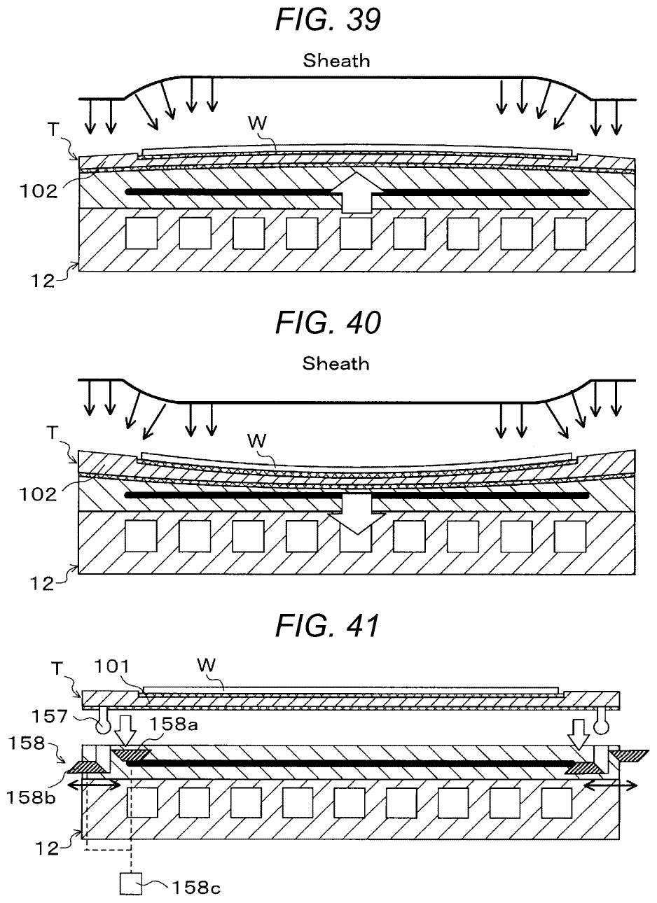

Specifically, for example, by making the attraction force on the outer peripheral portion of the tray Tw stronger than the attraction force on the central portion of the tray Tw, an attraction shape of the tray Tw in a cross-sectional view is deformed into an upper convex shape as illustrated in FIG. 39. Then, the upper surface height of the outer peripheral portion of the wafer W or the annular portion 102 is lower than the upper surface height of the central portion of the wafer W, so that the plasma sheath position formed above the outer peripheral portion of the wafer W is lowered, and as illustrated in FIG. 39, the incidence angle of ions can be tilted toward the inner side in the radial direction of the wafer W.

On the other hand, for example, by making the attraction force on the outer peripheral portion of the tray Tw weaker than the attraction force on the central portion of the tray Tw, an attraction shape of the tray Tw in a cross-sectional view is deformed into an upper concave shape as illustrated in FIG. 40. Then, an upper surface height of the outer peripheral portion of the wafer W or the annular portion 102 is higher than an upper surface height of the central portion of the wafer W, so that a plasma sheath position formed above the outer peripheral portion of the wafer W becomes higher, and as illustrated in FIG. 40, an incidence angle of ions can be tilted to an outer side in the radial direction of the wafer W.

According to the present embodiment, by controlling the attraction force in a surface of the tray Tw according to a consumption level (consumed amount) of the annular portion 102 of the tray T or the purpose of etching processing, the incidence angle of ions on the wafer W can be controlled, and tilting of an etched groove formed in the outermost peripheral portion of the wafer W can be controlled.

### (2) Clamp Holding

In the examples illustrated in FIGS. 37 to 40 described above, a case where the tray Tw is electrostatically attracted by the electrostatic chuck 14 of the substrate support 12 has been described by way of example. However, a method of holding the tray Tw on the substrate support 12 is not limited thereto. Therefore, the substrate support 12 does not need to include the electrostatic chuck 14 in the wafer processing module 10.

Specifically, for example, as illustrated in FIG. 41, a plurality of, for example, two or more pin members 157 may be provided on a lower surface side of the tray T, and after the pin members 157 are inserted into fixing holes formed in the substrate support 12, the tray T and the substrate support 12 may be mechanically held and fixed by a lock mechanism 158. The pin member 157 and the lock mechanism 158 preferably have a configuration in which the pin member 157 is pulled into the fixing hole (the substrate support 12) when the tray T is fixed (locked) to the substrate support 12, and the pin member 157 is pushed upward from the fixing hole (the substrate support 12) when the pin member 157 is separated (unlocked). In this manner, by locking the pin member 157 provided in the tray T to the substrate support 12, adhesiveness (surface pressure) between the tray T and the substrate support 12 (the electrostatic chuck 14) can be improved, and heat transfer performance can be improved, so that the cooling efficiency of the wafer W can be improved.

A structure of the lock mechanism 158 is not particularly limited as long as the lock mechanism 158 can improve adhesiveness between the substrate support 12 (the electrostatic chuck 14) and the tray T when the tray T is fixed (locked). For example, the lock mechanism 158 may be a clamp chuck mechanism. As illustrated in FIG. 41, a pull-in member 158a having a tapered shape for pulling in the pin member 157 and a push-out member 158b having a tapered shape for pushing out the pin member 157 may be moved in a horizontal direction by a slide mechanism 158c.

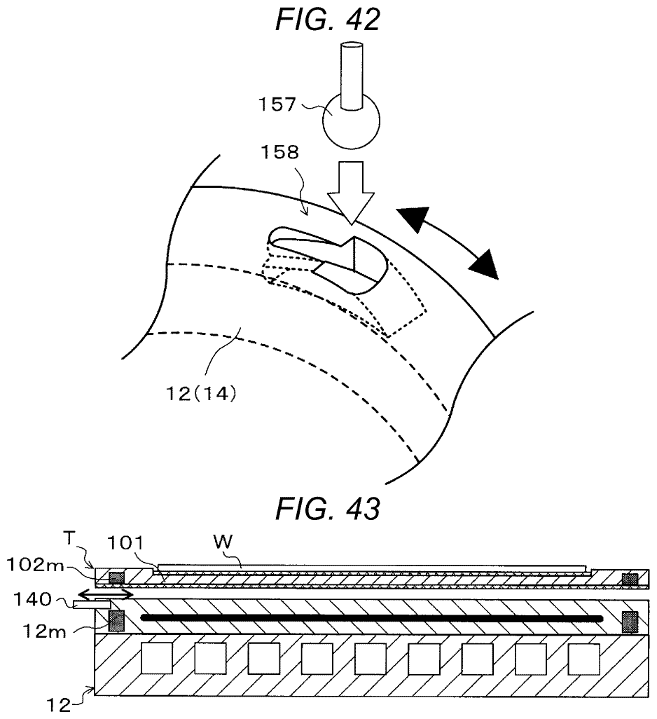

Alternatively, for example, the lock mechanism 158 may be a ring rotation mechanism. As illustrated in FIG. 42, the lock mechanism 158 may be configured to be rotatable in a circumferential direction relative to the pin member 157 after the pin member 157 is inserted into a fixing hole. In this case, the rotation mechanism that rotates the tray T and the substrate support 12 relative to each other may be a motor. In this case, the ring rotation mechanism may rotate only the lock mechanism 158 relative to the pin member 157, or may rotate the entire substrate support 12 relative to the pin member 157. When only the lock mechanism 158 is configured to be rotatable, the structure of the lock mechanism 158 can be miniaturized. When the entire substrate support 12 is configured to be rotatable, the structure of the lock mechanism 158 is enlarged. On the other hand, when the liquid heat transfer material is supplied through the through-holes 13h and 14h (see FIG. 25), the through-holes 13h and 14h can be moved in the circumferential direction by the rotation at the time of transferring the tray T and at the time of supplying the liquid heat transfer material. In other words, both the transfer of the tray T and the supply of the liquid heat transfer material can be achieved without shifting a position of the through-hole 101h formed in the tray T with respect to formation positions of the through-holes 13h and 14h in the circumferential direction and/or the radial direction.

### (3) Magnetic Force Holding

For example, the tray Tw may be attracted and held by a magnetic force onto the substrate support 12.

Specifically, as illustrated in FIG. 43, magnets 102m and 12m are disposed inside the annular portion 102 of the tray T and at an outer peripheral portion inside the substrate support 12 corresponding to the annular portion 102 (position opposite to the annular portion 102). An electromagnet or a permanent magnet can be selected as the magnets 102m and 12m disposed inside the annular portion 102 and the substrate support 12. Then, by placing the tray Tw above the substrate support 12 where the magnet 12m is disposed such that the magnet 12m and the magnet 102m face each other, a magnetic force with the magnet 12m and the magnet 102m serving as two poles is generated, and the tray Tw can be attracted and held on the substrate support 12.

In this case, for example, as illustrated in FIG. 43, a demagnetizer 140 is configured to allow free insertion and removal between the annular portion 102 of the tray Tw and the outer peripheral portion of the substrate support 12. Accordingly, when the demagnetizer 140 is disposed between the annular portion 102 and the substrate support 12, the magnetic force generated between the magnet 12m and the magnet 102m is removed, and the tray Tw can be transferred from the tray support surface of the substrate support 12.

In this manner, in the wafer processing module 10 according to the present embodiment, the tray T may be configured to be attracted and held onto the substrate support 12 by placing magnets inside the tray T and the substrate support 12.

### (4) Vacuum Attraction

The substrate support 12 of the wafer processing module 10 may include a vacuum chuck instead of the electrostatic chuck 14. In this case, an elastic heat transfer sheet is preferably selected as the second heat transfer material 105 disposed at least on the lower surface side of the tray T.

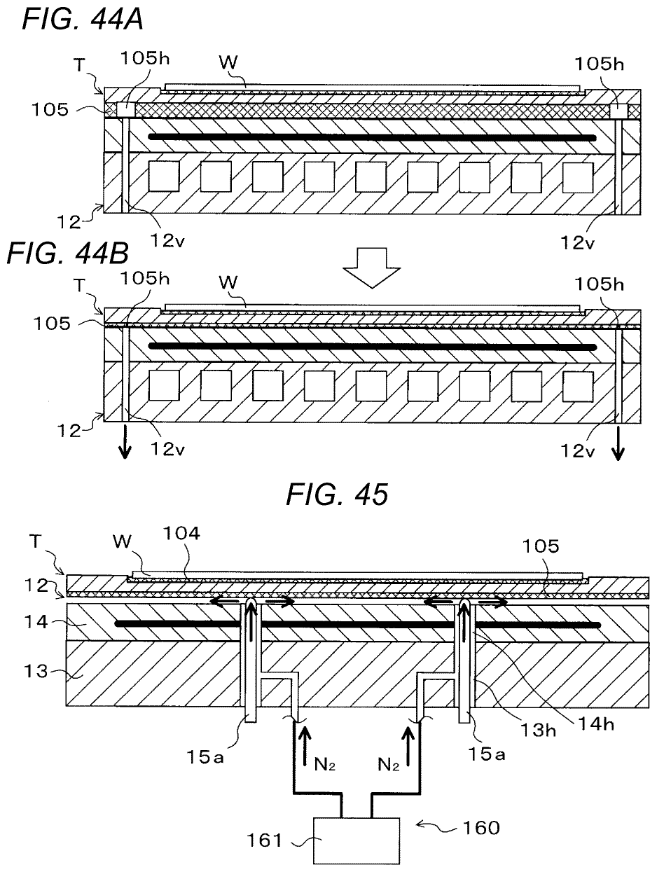

Specifically, for example, as illustrated in FIG. 44A, through-holes 105h are formed in the second heat transfer material 105 (heat transfer sheet) disposed on the lower surface side of the tray T at positions corresponding to vacuum lines 12v formed in the substrate support 12 in a plan view. Then, as illustrated in FIG. 44B, a vacuum pump connected to the vacuum line 12v is activated to attract and hold the tray Tw on the tray support surface of the substrate support 12 by a vacuum force.

In this case, the second heat transfer material 105 is compressed in a thickness direction along with pressing of the tray T onto the tray support surface by the vacuum force by selecting an elastic heat transfer sheet as the second heat transfer material 105. In this manner, the through-hole 105h is closed by plastic deformation of the second heat transfer material 105, and the entire surface of the tray T and the substrate support 12 come into contact with each other via the second heat transfer material 105, so that the tray T can be appropriately vacuum attracted and the cooling efficiency of the wafer W placed on the tray T can be improved.

<Method of Separating Tray from Electrostatic Chuck>

Next, an example of a method of separating the tray Tw fixed to the substrate support 12 (the electrostatic chuck 14) as described above from the substrate support 12 will be described.

As described above, the substrate support 12 according to the present embodiment is provided with the lifter 15, and the tray Tw is supported from below by the lift pin 15a and is configured to be detachable from the tray support surface of the substrate support 12 (the electrostatic chuck 14). However, when the tray Tw is separated from the substrate support 12 using the lift pin 15a, there is a concern that the tray Tw may not be easily separated from the tray support surface due to, for example, the influence of residual attraction or vacuum attraction. Then, when the tray Tw is lifted by the lift pin 15a in a state where there is residual attraction or the like, there is a concern that the tray T or the wafer W may be damaged due to overload.

Therefore, in the wafer processing module 10 according to the present embodiment, an inert gas (for example, a N₂ gas) is supplied to an interface between the tray Tw and the substrate support 12 in order to prevent the damage caused by the overload related to the lift-up described above.

More specifically, as illustrated in FIG. 45, an inert gas supply flow path 161 connected to a gas supply 160 provided with a gas source is added to the through-holes 13h and 14h through which the lift pins 15a for lifting and lowering the tray Tw are inserted. Then, when the tray Tw is to be separated, the supply of the inert gas is started before the tray Tw is lifted by the lift pins 15a, and thus the separation of the tray Tw from the substrate support 12 is assisted by pressurizing the interface between the tray Tw and the substrate support 12. The gas supply 160 may be shared with the gas supply 20 illustrated in FIG. 2.

According to the present embodiment, the tray Tw can be easily removed by supplying the inert gas when the tray Tw is separated from the substrate support 12 as described above.

As described above, the substrate support 12 is formed with a plurality of through-holes 13h and 14h, three through-holes 13h and 14h in the present embodiment, through which the three lift pins 15a are inserted. However, the inert gas for separating the tray Tw may be supplied to at least one of the through-holes 13h and 14h.

In the embodiment described above, the inert gas (N₂ gas) is supplied to the interface between the tray Tw and the substrate support 12. However, the supply is not limited to the inert gas as long as the interface between the tray Tw and the substrate support 12 can be appropriately pressurized in vacuum. Specifically, for example, the above-described ionic liquid may be supplied to the interface between the tray Tw and the substrate support 12 when the tray Tw is separated.

### <Operations and Effects of Techniques of Present Disclosure>

In the wafer processing system 1 according to the technique of the present disclosure, the wafer W to be processed is placed on the tray T, and the tray T and the wafer W are transferred and processed together. Further, the first heat transfer material 104 and the second heat transfer material 105 are disposed at the interface between the tray T and the wafer W (inside the recess 103) and the interface between the tray T and the substrate support 12 (the electrostatic chuck 14), and thus the wafer W and the tray T are in full contact with each other, and the tray T and the substrate support 12 (the electrostatic chuck 14) are in full contact with each other. Accordingly, in the wafer processing module 10 according to the technique of the present disclosure, the heat transfer performance from the wafer W to the substrate support 12 can be improved, and the entire surface of the wafer W can be appropriately and uniformly cooled by the heat transfer fluid flowing through the flow path 13a formed in the base 13 of the substrate support 12.

In this configuration, the wafer W and the tray T can be easily loaded and unloaded simply by lifting or placing the tray T (Tw) by the action of the pin 110 and the hole 111.

By lifting or placing the tray T (Tw) on the rack 300 of the tray stocker 6, a step of transferring the tray T related to loading and unloading of the wafer W and the tray T can be omitted, and further, throughput can be improved.

Further, since the wafer W and the tray T are in full contact with each other, and the tray T and the substrate support 12 (the electrostatic chuck 14) are in full contact with each other as described above, it is possible to prevent the occurrence of a gap between the back surface of the wafer W and the outer peripheral portion of the electrostatic chuck 14 as in the related art. Therefore, deposition (so-called “shoulder deposition”) on particularly a shoulder portion of the outer peripheral portion of the electrostatic chuck 14 is prevented, and a frequency of a cleaning (waferless dry cleaning (WLDC)) step of the wafer processing module 10 can be reduced.

Further, in the wafer processing module 10 according to the technique of the present disclosure, the pressing force (surface pressure) of the tray T against the tray support surface of the substrate support 12 is improved by electrostatic attraction or clamp holding as described above. Accordingly, the heat transfer performance from the wafer W to the substrate support 12 can be further improved, and the cooling efficiency of the wafer W can be further appropriately improved.

In the wafer processing module 10 according to the technique of the present disclosure as described above, cooling of the wafer W can be uniformly performed in a surface by interposing the first heat transfer material 104 and the second heat transfer material 105. However, temperature singularities with reduced cooling efficiency may occur in portions where a through-hole (for example, the through-holes 13h and 14h for the lift pins 15a, a supply hole for a He gas, and a through-hole through which a cable for supplying electrostatic attraction power and RF power is inserted) is formed in a surface of the substrate support 12.

Therefore, in the substrate support 12 disposed in the wafer processing module 10 according to the present embodiment, it is preferable that the through-hole formed in the substrate support 12 does not overlap at least the wafer W to be processed in a vertical direction. More specifically, it is preferable to change positions where the through-hole is formed in the tray Tw held on the tray support surface of the substrate support 12, so that the through-hole is not formed immediately below the disk portion 101 (the recess 103) on which the wafer W is placed.

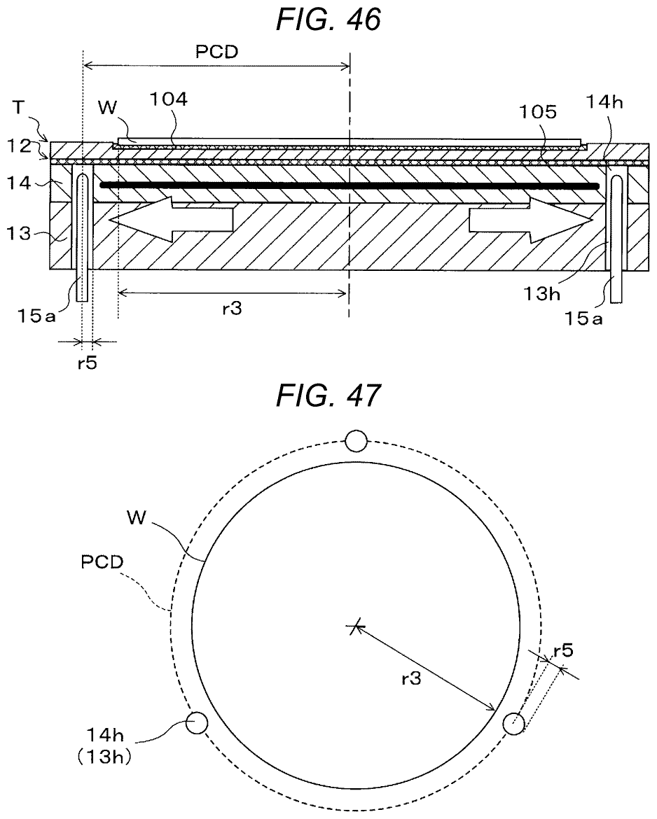

In this case, the position where the through-hole is formed is preferably immediately below the annular portion 102 in the tray T as illustrated in FIGS. 46 and 47. In this case, it is preferable to set a pitch circle diameter (PCD) of a through-hole (the through-holes 13h and 14h in the illustrated example) to be larger than the sum of the outer diameter r3 (see FIG. 4) of the wafer W to be processed and a hole diameter r5 of the through-hole (PCD>r3+r5).

According to the present embodiment, the through-holes formed in the substrate support 12 as described above, for example, the through-holes 13h and 14h for the lift pins 15a and the supply hole for a He gas, and the through-hole through which a cable for supplying electrostatic attraction power and RF power is inserted, are disposed in a manner of not overlapping the wafer W in the vertical direction. Accordingly, occurrence of temperature singularities in a surface of the wafer W during the wafer processing can be prevented, and the wafer W can be more appropriately cooled.

In the above description, a plasma processing module that performs plasma processing such as etching on the wafer W has been described as an example of the wafer processing module 10. However, the wafer processing performed in the wafer processing module 10 is not limited to the plasma processing, and for example, the technique according to the present disclosure can be applied as long as processing requires to maintain a temperature of the wafer W to be processed to be uniform in a surface.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above.

1. A substrate processing system comprising:
a processing module having a substrate support and configured to process a substrate;
a vacuum transfer module connected to the processing module, the vacuum transfer module having an interior maintained at a sub-atmospheric pressure;
an atmospheric transfer module connected to the vacuum transfer module via a load-lock module, the atmospheric transfer module having an interior maintained at the atmospheric pressure; and
a transferer configured to transfer, to the processing module, the substrate and a tray on which the substrate is placed, wherein
the tray is formed with
a recess provided in an upper surface of the tray to accommodate the substrate, and
a hole penetrating the tray from the recess to a lower surface of the tray, and
the hole movably holds a pin that protrudes from either the recess or the lower surface in a state where the pin is inserted into the hole.

2. The substrate processing system according to claim 1, wherein
the tray further includes the pin, and
the pin is inserted into the hole.

3. The substrate processing system according to claim 2, wherein
a lower end of the pin protrudes from the lower surface of the tray in a first state where the substrate is accommodated in the recess, and
an upper end of the pin comes into contact with the substrate and protrudes from the recess in a second state including a transition state where the substrate is loaded into and unloaded from the recess.

4. The substrate processing system according to claim 3, wherein
the upper end of the pin includes an upper end surface that comes into surface contact with the substrate in the first state.

5. The substrate processing system according to claim 4, wherein
the pin includes a head that includes the upper end, and
the head has a shape for locking the pin by a force from the recess to the lower surface so that the pin does not come out from the hole.

6. The substrate processing system according to claim 5, wherein
the head has a conical shape with the upper end surface serving as a bottom surface, or a columnar shape with the upper end surface serving as one bottom surface.

7. The substrate processing system according to claim 6, wherein
the pin includes a base that includes the lower end, and
the base has a shape for locking the pin by a force from the lower surface to the recess so that the pin does not come out of the hole.

8. The substrate processing system according to claim 7, wherein
the base has a conical shape with a lower end surface included in the lower end serving as a bottom surface, or a columnar shape with the lower end surface serving as one bottom surface.

9. The substrate processing system according to claim 1, wherein the hole has an inner surface that comes into contact with an outer surface of the pin.

10. The substrate processing system according to claim 3, further comprising:
a substrate loading and unloading portion, wherein
the substrate loading and unloading portion is configured to allow the tray to be placed thereon,
the upper end of the pin protrudes from the recess in a third state where the tray in which the substrate is not accommodated in the recess is placed on the substrate loading and unloading portion, and
the substrate is loaded onto and unloaded from the tray by shifting the first state, the second state, and the third state on the substrate loading and unloading portion.

11. The substrate processing system according to claim 10, further comprising:
controller circuitry configured to:
(a) control the transferer to transfer the tray to the substrate loading and unloading portion, place the tray on the substrate loading and unloading portion, and set the tray in the third state,
(b) control the transferer to transfer the substrate to the substrate loading and unloading portion, place the substrate on the upper end of the pin of the tray, and set the tray in the second state,
(c) control the transferer to lift the tray in the second state, and set the tray in the first state,
(d) control the transferer to transfer the tray in the first state from the substrate loading and unloading portion to the processing module,
(e) control the processing module to process the substrate,
(f) control the transferer to transfer the tray in the first state from the processing module to the substrate loading and unloading portion,
(g) control the transferer to place the tray in the first state on the substrate loading and unloading portion, and set the tray in the second state, and
(h) control the transferer to lift the substrate from the tray in the second state, and transfer the substrate from the substrate loading and unloading portion.

12. The substrate processing system according to claim 11, wherein
the controller circuitry executes control including (b) to (h) by using, as the tray in (b), the tray in the third state that is placed on the substrate loading and unloading portion after (h).

13. The substrate processing system according to claim 10, further comprising:
a storage, wherein
the storage includes the substrate loading and unloading portion, and
the tray in the third state is stored on the substrate loading and unloading portion.

14. The substrate processing system according to claim 13, further comprising:
controller circuitry configured to:
(a) control the transferer to transfer the substrate to the substrate loading and unloading portion in the storage module, place the substrate on the upper end of the pin of the tray, and set the tray in the second state,
(b) control the transferer to lift the tray in the second state, and set the tray in the first state,
(c) control the transferer to transfer the tray in the first state from the substrate loading and unloading portion to the processing module,
(d) control the processing module to process the substrate,
(e) control the transferer to transfer and place the tray in the first state from the processing module onto the substrate loading and unloading portion in the storage module, and set the tray in the second state, and
(f) control the transferer to lift the substrate from the tray in the second state, and transfer the substrate from the substrate loading and unloading portion.

15. The substrate processing system according to claim 14, wherein
in (a), the controller circuitry is further configured to select the tray provided with the recess having an inner diameter corresponding to an outer diameter of the substrate, and control the transferer to place the substrate on the selected tray.

16. A storage for storing a tray used in a substrate processing system for transferring and processing a substrate placed on the tray, the storage comprising:
a substrate loading and unloading portion, wherein
the tray is formed with
a recess provided in an upper surface of the tray and configured to accommodate the substrate, and
a hole penetrating the tray from the recess to a lower surface of the tray, and
the hole is configured to movably hold a pin configured to protrude from either the recess or the lower surface in a state where the pin is inserted into the hole.

17. The storage module according to claim 16, wherein
the tray further includes the pin, and the pin is inserted into the hole, and
an upper end of the pin protrudes from the recess in a state where the tray in which the substrate is not accommodated in the recess is placed on the substrate loading and unloading portion.

18. A substrate processing method comprising:
(a) transferring, by a transfer mechanism, a tray to a substrate loading and unloading portion and placing the tray on the substrate loading and unloading portion in a third state, the tray having a recess in an upper surface of the tray, a hole penetrating the tray from the recess to a lower surface of the tray, and a pin inserted into the hole and movably held therein, wherein the third state is a state in which an upper end of the pin protrudes from the recess and a lower end of the pin does not protrude from the lower surface of the tray;
(b) transferring, by the transfer mechanism, a substrate to the substrate loading and unloading portion and placing the substrate on the upper end of the pin of the tray in a second state in which the upper end of the pin contacts the substrate;
(c) lifting, by a lifter, the tray in the second state from the substrate loading and unloading portion such that the tray is set in a first state in which the lower end of the pin protrudes from the lower surface of the tray and the substrate is accommodated in the recess;
(d) transferring, by the transfer mechanism, the tray in the first state from the substrate loading and unloading portion to a processing module;
(e) processing, by the processing module, the substrate accommodated in the recess of the tray;
(f) transferring, by the transfer mechanism, the tray in the first state from the processing module to the substrate loading and unloading portion;
(g) placing, by the transfer mechanism, the tray on the substrate loading and unloading portion such that the tray is set in the second state; and
(h) lifting, by the lifter, the substrate from the tray in the second state, and transferring the substrate from the substrate loading and unloading portion.

19. The substrate processing method according to claim 18, further comprising:
selecting, from among a plurality of trays having recesses of different inner diameters, the tray having the recess with an inner diameter corresponding to an outer diameter of the substrate,
wherein the selected tray is the tray placed on the substrate loading and unloading portion in step (a) and on which the substrate is placed in step (b).

20. The substrate processing method according to claim 18, wherein steps (b) through (h) are repeated using, as the tray in step (b), the tray remaining on the substrate loading and unloading portion in the third state after step (h).
